(19) United States
(12) Patent Application Publication
(10) Pub. No.: US 2023/0299242 A1
(43) Pub. Date: Sep. 21, 2023

(54) LIGHT EMITTING DEVICES AND USES THEREOF IN DISPLAYS

(71) Applicant: Zhejiang Brilliant Optoelectronic Technology Co.,Ltd., Taizhou (CN)

(72) Inventors: Chao MIN, Taizhou (CN); Chacai LIANG, Taizhou (CN); Caifa PAN, Taizhou (CN)

(73) Assignee: Zhejiang Brilliant Optoelectronic Technology Co.,Ltd., Taizhou (CN)

(21) Appl. No.: 18/300,734

(22) Filed: Apr. 14, 2023

Related U.S. Application Data
(63) Continuation of application No. PCT/CN2021/123754, filed on Oct. 14, 2021.

(30) Foreign Application Priority Data
Oct. 14, 2020 (CN) 202011099557.7

(51) Int. Cl. H01L 33/50; H10K 59/38; C09K 11/06; C07F 5/02; C07F 7/08

(52) U.S. Cl. CPC H01L 33/502; C07F 5/027; C07F 7/0816; C09K 11/06; H10K 59/38; C09K 2211/1007; C09K 2211/1018

(57) ABSTRACT

Discloded is a light emitting devices including an electroluminescent unit that emits the light of wavelength I, and a color conversion layer that absorbs the light of wavelength I and emits the light of wavelength II are disclosed. The color conversion layer comprises at least one color conversion material having a structural unit of formula (1) or (2). Display devices containing the light emitting devices are also disclosed.

### CROSS-REFERENCE TO RELATED APPLICATIONS

This application is a continuation of International Application No. PCT/CN2021/123754, filed on Oct. 14, 2021, which claims priority to Chinese Patent Application No. 202011099557.7, filed on Oct. 14, 2020. All of the aforementioned applications are incorporated herein by reference in their entireties.

### TECHNICAL FIELD

The present disclosure relates to light emitting devices and their uses in displays.

### BACKGROUND

According to the principles of colorimetry, the narrower the full width at half maximum (FWHM) of the lights perceived by human eyes are, the higher the color purity, and thus the more vivid the color display would be. Display devices with narrow FWHM red, green and blue primary light are able to show vivid views with high color gamut and high visual quality.

The current mainstream full-color displays are achieved mainly in two ways. The first method is to actively emit red, green and blue lights, typically such as RGB-OLED display, RGB-Micro-LED display, etc. Due to the need of manufacturing light emitting devices of all three colors, the complexity of processing leads to low yields, and the high-resolution display over 800 ppi is difficult to realize. The second method is to use color converters to convert the single-color light from the light emitting devices into different colors, thereby achieving a full-color display. In this case, the fabrication of the light emitting devices is much simpler, and thus higher yield. Furthermore, the manufacture of the color converters can be achieved by different technologies, such as vapor deposition, inkjet printing, transfer printing and photolithography, etc., appliable to a variety of display products with very different resolution requirements from low resolution large-size TV (around only 50ppi) to high resolution silicon-based micro-display (over 3000ppi).

Currently, there are mainly two types of color conversion materials used in mainstream color converters. The first one is organic dyes, comprising various organic conjugated small molecules or polymers with chromophores. Due to the lack of rigidity in the molecular structures, intra-molecular thermal relaxations are always non-negligible, leading to the large FWHMs (typically over 60 nm) of their emission spectra. The second one is inorganic nanocrystals, commonly known as quantum dot, which are nanoparticles of inorganic semiconductor material (InP, CdSe, CdS, ZnSe, etc.) with a diameter of 2-8 nm. The small size of these materials leads to quantum confinement effects, resulting in photoluminescent emissions with a specific frequency, which are highly dependent on the particle size. In this sense, the color of their emission can be readily tuned by adjusting the sizes. Limited by the current synthesis and separation technology of quantum dots, FWHMs of CD-containing quantum dots typically range from 25 to 40 nm, which meets the display requirements of NTSC for color purity. Meanwhile, Cd-free quantum dots generally come with larger FWHMs of 55-75 nm. Since Cd is considered highly hazardous to environment and human health, most countries have prohibited the use of Cd-containing quantum dots to produce electronic products. In addition, because the not-sufficiently-large extinction coefficient of quantum dots, the rather thick film required for complete color conversion is rather high.

Therefore, new color conversion materials still need to be further developed, in order to meet the requirements of full-color display.

### SUMMARY

In one aspect, the present disclosure provides a light emitting device comprising an electroluminescent unit and a color conversion layer (CCL), wherein the color conversion layer comprises at least one color conversion material (CCM) having a structural unit of formula (1) or (2):

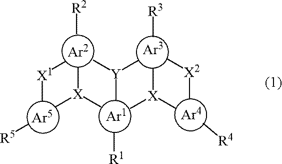

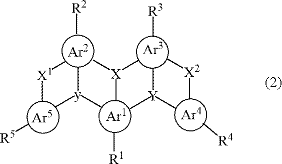

wherein :
each X independently represents N, C(R⁶), or Si(R⁶);
each Y independently represents B, P=O, C(R⁶), or Si(R⁶);
each of Ar¹, Ar², and Ar³ is independently an aromatic containing 5 to 24 ring atoms, or a heteroaromatic group containing 5 to 24 ring atoms;
each of Ar⁴ and Ar⁵ is independently null, an aromatic group containing 5 to 24 ring atoms, or a heteroaromatic group containing 5 to 24 ring atoms;
when neither Ar⁴ nor Ar⁵ is null, each X is selected from the group consisting of N, C(R⁶), and Si(R⁶), each Y is selected from the group consisting of B, P═O, C(R⁶), and Si(R⁶) ;
when either Ar⁴ and/ or Ar⁵ is null, the corresponding X and Y are each independently selected from the group consisting of N(R⁶), C(R⁶R⁷), Si(R⁶R⁷), C═O, O, C═N(R⁶), C═C(R⁶R⁷), P(R⁶), P(═O)R⁶, S, S═O, and SO₂;
each of X¹, X² is independently null or a bridging group, and preferably can be independently selected from null, single bond, N(R⁶), C(R⁶R⁷), Si(R⁶R⁷), O, C═N(R⁶), C═C(R⁶R⁷), P(R⁶), P(═O)R⁶, S, S═O, or SO₂;
R¹ to R⁷ are independently selected from the group consisting of —H, —D, —F, —Cl, Br, I, —CN, —NO₂, —CF₃, B(OR₂)₂, Si(R₂)₃, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/ cyclic alkyl group, a C₃-C₂₀ branched/ cyclic haloalkyl group, a C₃-C₂₀ branched/ cyclic alkoxy group, a C₃-C₂₀ branched/ cyclic thioalkoxy group, a C₃-C₂₀ branched/ cyclic silyl group, a C₁-C₂₀ ketone group, a C₂-C₂₀ alkoxycarbonyl group, a C₇-C₂₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate/isothiocyanate group, a hydroxyl group, a nitro group, a CF₃ group, Cl, Br, F, a substituted/unsubstituted aromatic/ heteroaromatic group containing 5 to 40 ring atoms, an aryloxy/heteroaryloxy group containing 5 to 40 ring atoms, an arylamine/ heteroarylamine group containing 5 to 40 ring atoms, a disubstituted unit in any position of the above substituents and any combination thereof, wherein one or more of the substituent groups can form a monocyclic or polycyclic aliphatic or aromatic ring system with each other and/or with the ring bonded to the groups.

In addition or alternatively, the electroluminescent unit is selected from: an OLED (organic light emitting diode), a TFT-LCD (thin-film transistor liquid crystal display), a LED (light emitting diode), a QLED (quantum dot electroluminescent device), an OLEC (organic light emitting electrochemical cell), an OLET (organic light emitting transistor), a PeLED (perovskite electroluminescent device), a micro-LED (micro-light emitting diode), or other light emitting devices.

In addition or alternatively, the color conversion layer (CCL) can absorb the light of wavelength I and emit the light of wavelength II.

In addition or alternatively, the emission spectrum of the electroluminescent unit at least partially overlaps with the absorption spectrum of the color conversion material.

In addition or alternatively, the electroluminescent unit emits UV or blue light.

In addition or alternatively, the FWHM of the spectrum of wavelength II emitted by the color conversion layer is less than 40 nm.

In addition or alternatively, the color conversion layer can be either an uniform thin layer or a patterned thin layer with a thickness of 20 nm to 20 µm.

In addition or alternatively, the color conversion layer can be prepared by vapor deposition, ink-jet printing, screen printing, gravure printing, or post-coating photolithography.

In another aspect, the present disclosure also provides a display device comprising a number of sub-pixels, while at least one of the sub-pixels comprises a light emitting device as described herein.

### DETAILED DESCRIPTION

The present disclosure provides a light emitting device with a relatively narrow FWHM, and the FWHM of the emitted light of the disclosed narrow-FWHM light emitting device is generally less than 40 nm, preferably less than 35 nm, more preferably less than 30 nm, and most preferably less than 28 nm.

The present disclosure also provides a multi-color display device utilizing the narrow-FWHM light emitting device, which has an excellent color gamut.

In order to make the objects, technical solutions, and effects of the present disclosure more clear and definite, the present disclosure is further described in details below. It should be understood that the embodiments described herein are only intended to explain the present disclosure, and are not intended to limit the present disclosure.

As used herein, the terms “formulation”, “printing ink” and “inks” have the same meaning, and they are interchangeable with each other.

As used herein, the terms “host material”, “matrix material” have the same meaning, and they are interchangeable with each other.

As used herein, the term “substituted” means that a hydrogen atom of the compound is substituented.

As used herein, “the number of ring atoms” means that the number of atoms constituting the ring itself of a structural compound (e. g., a monocyclic compound, a fused ring compound, a cross-linked compound, a carbocyclic compound, and a heterocyclic compound) by covalent bonding. When the ring is substituted with a substituent, the atoms contained in the substituent are not included in the ring atoms. The above rule applies for all cases without further specfic description. For example, the number of ring atoms of a benzene ring is 6, the number of ring atoms of a naphthalene ring is 10, and the number of ring atoms of a thienyl group is 5.

In one aspect, the present disclosure provides a light emitting device comprising an electroluminescent unit and a color conversion layer (CCL), wherein the color conversion layer comprises at least one color conversion material (CCM) having a structural unit of formula (1) or (2):

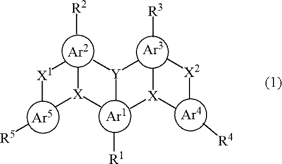

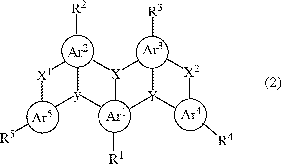

wherein :
each X independently represents N, C(R⁶), or Si(R⁶);
each Y independently represents B, P═O, C(R⁶), or Si(R⁶);
each of Ar¹ to Ar³ is independently an aromatic group containing 5 to 24 ring atoms or a heteroaromatic group containing 5 to 24 ring atoms;
each of Ar⁴ to Ar⁵ is independently null, an aromatic groups containing 5 to 24 ring atoms, or a heteroaromatic groups containing 5 to 24 ring atoms;
when neither Ar⁴ nor Ar⁵ is null, each X is selected from the group consisting of N, C(R⁶), and Si(R⁶), each Y is selected from the group consisting of B, P═O, C(R⁶), and Si(R⁶) ;
when Ar⁴ and/ or Ar⁵ is null, the corresponding X and Y are each independently selected from N(R⁶), C(R⁶R⁷), Si(R⁶R⁷), C═O, O, C═N(R⁶), C═C(R⁶R⁷), P(R⁶), P(═O)R⁶, S, S═O, or SO₂;
each of X¹, X² is independently null or a bridging group, and preferably can be independently selected from null, single bond, N(R⁶), C(R⁶R⁷), Si(R⁶R⁷), O, C═N(R⁶), C═C(R⁶R⁷), P(R⁶), P(═O)R⁶, S, S═O, or SO₂;
R¹ to R⁷ are independently selected from the group consisting of —H, —D, —F, —Cl, Br, I, —CN, —NO₂, —CF₃, B(OR₂)₂, Si(R₂)₃, a C₁-C₂₀linear alkyl group, a C₁-C₂₀ linear haloalkyl group, a C₁-C₂₀ linear alkoxy group, a C₁-C₂₀ linear thioalkoxy group, a C₃-C₂₀ branched/ cyclic alkyl group, a C₃-C₂₀ branched/ cyclic haloalkyl group, a C₃-C₂₀ branched/ cyclic alkoxy group, a C₃-C₂₀ branched/ cyclic thioalkoxy group, a C₃-C₂₀ branched/ cyclic silyl group, a C₁-C₂₀ ketone group, C₂-C₂₀ alkoxycarbonyl group, a C₇-C₂₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate/isothiocyanate group, a hydroxyl group, a nitro group, a CF₃ group, Cl, Br, F, a substituted/unsubstituted aromatic/ heteroaromatic group containing 5 to 40 ring atoms, an aryloxy/heteroaryloxy group containing 5 to 40 ring atoms, an arylamine/ heteroarylamine group containing 5 to 40 ring atoms,a disubstituted unit in any position of the above substituents and any combination thereof, wherein one or more of the substituent groups can form a monocyclic or polycyclic aliphatic or aromatic ring system with each other and/or with the ring bonded to the groups.

In multiple occurrences, Ar¹ to Ar⁵ are independently selected from aromatic groups containing 2 to 24 carbon atoms, such as benzene, biphenyl, triphenylbenzene, triphenylene, benzphenanthrene, naphthalene, anthracene, phenalene, phenanthrene, fluorene, pyrene, chrysene, perylene, chrysene; or Ar¹ to Ar⁵ are independently selected from heteroaromatic groups containing 2 to 24 carbon atoms, such as furan, thiophene, pyrrole, benzofuran, benzothiophene, dibenzothiophene, dibenzofuran, carbazole, pyrazole, imidazole, triazole, isoxazole, thiazole, oxadiazole, oxatriazole, oxadiazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, phthalazine/cinnoline, quinazoline, quinoxaline, naphthalene,phthalide, pteridine, xanthene, acridine, phenazine, phenothiazine, phenazine, dibenzoselenophene, benzoselenophene, benzofuropyridine, indolocarbazole, pyridylindole, pyrrolodipyridine, furodipyridine, benzothienopyridine, thienodipyridine, benzoselenophenopyridine or selenophenodipyridine. In some embodiments, Ar¹ to Ar⁵ are independently selected from functional groups containing 2 to 10 ring atoms, which may be the same or different types of cyclic aromatic hydrocarbon groups/ aromatic heterocyclic groups, and these groups are linked to one another directly or through at least one of the following groups, such as O, N, S, Si, P, B, chain structural units or aliphatic ring groups; wherein Ar¹, Ar², Ar³, Ar⁴, Ar⁵ can be further substituted independently by one or more R¹ to R⁵ groups respectively, or unsubstituted.

The term “aromatic group” refers to a hydrocarbon group consisting of at least one aromatic ring, including monocyclic groups and polycyclic systems. The term “heteroaromatic group” refers to a heteroaromatic group consisting of at least one heteroaromatic ring, including monocyclic groups and polycyclic systems. The polycyclic systems contain two or more rings, in which two carbon atoms are shared by two adjacent rings, i.e. fused ring. Specifically, at least one of the rings in the polycyclic rings are aromatic or heteroaromatic. For the purposes of the present disclosure, the aromatic ring groups or heteroaromatic groups comprise not only aromatic or heteroaromatic systems, but alsoa plurality of aromatic or heteroaromatic groups are interconnected by short non-aromatic units (for example by <10% of non-H atoms, more specifically 5% of non-H atoms, such as C, N or O atoms). Therefore, systems such as 9,9′-spirobifluorene, 9,9-diaryl fluorene, triarylamine, diaryl ethers, and other systems, should also be considered as aromatic groups for the purposes of this disclosure.

Specifically, preferred examples of the aromatic groups include: benzene, naphthalene, anthracene, phenanthrene, perylene, tetracene, pyrene, benzopyrene, triphenylene, acenaphthylene, fluorene, and derivatives thereof.

Specifically, preferred examples of heteroaromatic groups include: furan, benzofuran, thiophene, benzothiophene, pyrrole, pyrazole, triazole, imidazole, oxazole, oxadiazole, thiazole, tetrazole, indole, carbazole, pyrroloimidazole, pyrrolopyrrole, thienopyrrole, thienothiophene, furopyrrole, furofuran, thienofuran, benzisoxazole, benzisothiazole, benzimidazole, pyridine, pyrazine, pyridazine, pyrimidine, triazine, quinoline, isoquinoline, o-diazonaphthalene, quinoxaline, phenanthridine, pyrimidine, quinazoline, quinazolinone, and derivatives thereof.

In some embodiments, in the CCM described herein, the Ar¹ to Ar⁵ are aromatic groups or heteroaromatic groups containing 5 to 22 C. In some embodiments, the Ar¹ to Ar⁵ are aromatic groups or heteroaromatic groups containing 5 to 20 C. In some embodiments, the Ar¹ to Ar⁵ are aromatic or heteroaromatic groups containing 5 to 18 C.

In some embodiments, in the CCM described herein, the Ar¹ to Ar⁵ may comprise one or combinations of more than one of the following structural groups:

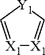

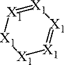

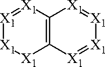

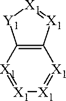

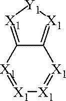

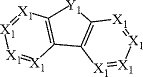

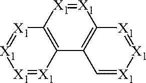

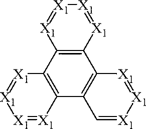

wherein:
X₁ at each occurrence, can independently be N or CR₅;
Y₁ at each occurrence, can be independently selected from CR₆R₇, SiR₆R₇, NR₆, C(═O), S, or O;
R₅, R₆ and R₇ are independently defined as R¹.

Further, each of the Ar¹ to Ar⁵ is independently selected from one or combinations of more than one of the following structural formulas, which can be further arbitrarily substituted:

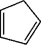

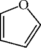

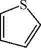

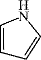

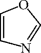

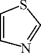

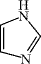

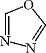

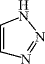

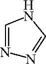

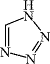

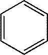

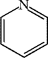

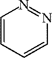

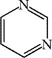

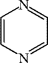

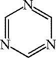

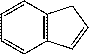

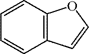

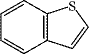

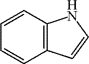

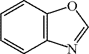

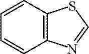

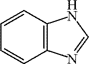

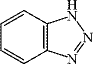

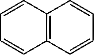

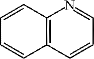

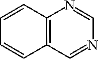

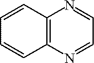

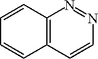

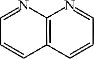

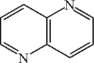

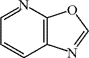

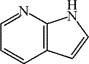

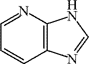

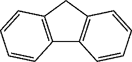 [SMILES: c1ccc2c(c1)Cc1ccccc1-2]

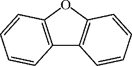 [SMILES: c1ccc2c(c1)oc1ccccc12]

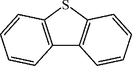 [SMILES: c1ccc2c(c1)sc1ccccc12]

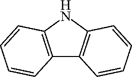 [SMILES: c1ccc2c(c1)[nH]c1ccccc12]

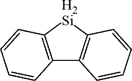

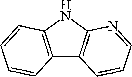 [SMILES: c1ccc2c(c1)[nH]c1ncccc12]

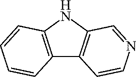 [SMILES: c1ccc2c(c1)[nH]c1cnccc12]

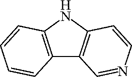 [SMILES: c1ccc2c(c1)[nH]c1ccncc12]

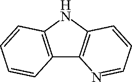 [SMILES: c1ccc2c(c1)[nH]c1cccnc12]

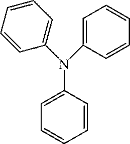 [SMILES: c1ccc(N(c2ccccc2)c2ccccc2)cc1]

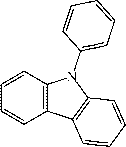 [SMILES: c1ccc(-n2c3ccccc3c3ccccc32)cc1]

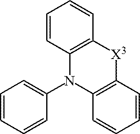

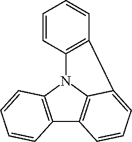 [SMILES: c1ccc2c(c1)c1cccc3c4ccccc4n2c13]

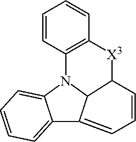

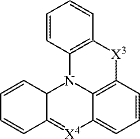

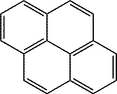 [SMILES: c1cc2ccc3cccc4ccc(c1)c2c34]

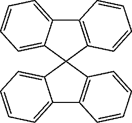 [SMILES: c1ccc2c(c1)-c1ccccc1C21c2ccccc2-c2ccccc21]

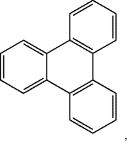

wherein each of X³, X⁴ is independently null or a bridging group.

In some embodiments, the color conversion layer comprises at least one color conversion material (CCM) having a structural unit of formula (1a) or (2a):

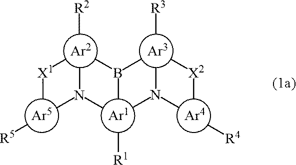

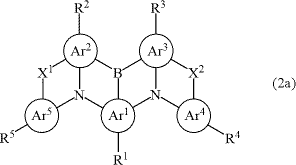

In some embodiments, at least one of X¹ or X² is null; particularly preferably, both are null, in which case the CCM comprises a structural unit of formula (1b) or (2b):

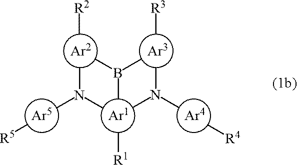

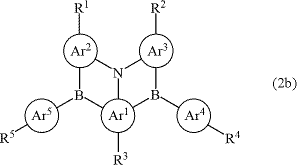

In some embodiments, at least one of X¹ or X² is a single bond; particularly preferably, both are single bonds, and the CCM comprises a structural unit of formula (1c) or (2c):

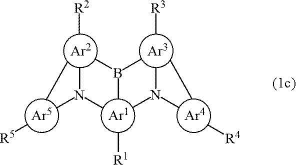

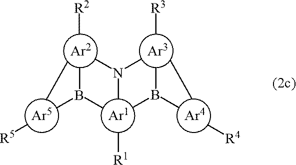

In some embdiments, X¹, X² at each occurrence are the same or different di-bridging group; the preferred di-bridging groups are selected form the following formulas:

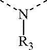

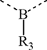

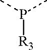

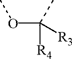

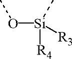

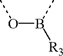

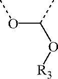

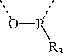

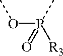

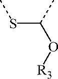

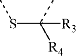

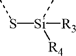

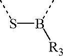

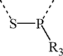

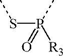

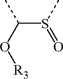

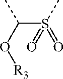

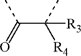

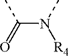

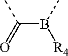

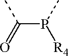

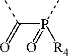

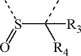

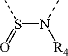

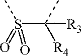

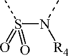

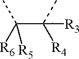

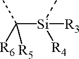

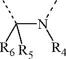

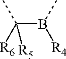

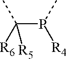

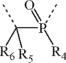

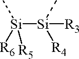

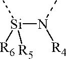

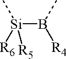

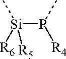

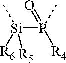

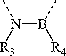

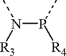

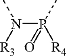

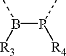

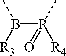

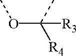

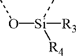

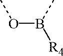

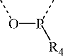

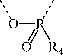

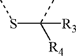

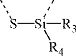

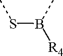

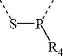

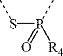

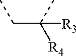

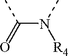

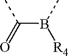

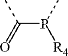

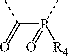

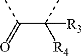

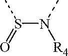

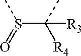

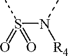

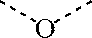

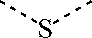

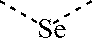

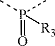

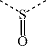

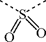

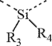

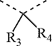

wherein R₃, R₄, R₅ and R₆ are identically defined as the above-mentioned R¹, and the dashed bonds refer to the covalent bonds connecting to the adjacent structural units.

For the purposes of the present disclosure, the aromatic ring systems contain 5 to 10 carbon atoms in the ring systems, the heteroaromatic ring systems contain 1 to 10 carbon atoms and at least one heteroatom in the ring systems, while the total number of carbon atoms and heteroatoms is at least 4. The heteroatoms are preferably selected from Si, N, P, O, S and/ or Ge, particularly preferably selected from Si, N, P, O and/ or S. For the purposes of the present disclosure, the aromatic ring groups or heteroaromatic groups contain not only aromatic or heteroaromatic systems, but also a plurality of aromatic or heteroaromatic groups are interconnected by short non-aromatic units (for example by <10% of non-H atoms, more specifically 5% of non-H atoms, such as C, N or O atoms). Therefore, systems such as 9,9′-spirobifluorene, 9,9-diaryl fluorene, triarylamine, diaryl ethers, and the like are also considered to be aromatic ring systems for the purpose of this disclosure.

For the purposes of the present disclosure, the any H atom on the CCM may be optionally substituted with a R1 group, wherein the preferred R1 may be selected from (1) a C1 to C10 alkyl group, particularly preferred as the following groups: methyl, ethyl, n-propyl, isopropyl, cyclopropyl, n-butyl, isobutyl, sec-butyl, t-butyl, cyclobutyl, 2-methylbutyl, n-pentyl, n-hexyl, cyclohexyl, n-heptyl, cycloheptyl, n-octyl, cyclooctyl, 2-ethylhexyl, trifluoromethyl, pentafluoromethyl, 2,2,2-trifluoroethyl, vinyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl, or octynyl; (2) a C1 to C10 alkoxy group, particularly preferably methoxy, ethoxy, n-propoxy, isopropoxy, n-butoxy, isobutoxy, sec-butoxy, tert-butoxy or 2-methylbutoxy; (3) a C2 to C10 aryl or heteroaryl group, which may be monovalent or divalent depending on the application, and in each case can also be optionally substituted with the group R1 mentioned above or may be attached, at any desired position, to an aromatic or heteroaromatic ring, particularly preferably selected from: benzene, naphthalene, anthracene, dihydropyrene, chrysene, pyrene, fluoranthene, naphthacene, pentacene, benzopyrene, furan, benzofuran, isobenzofuran, dibenzofuran, thiophene, benzothiophene, isobenzothiophene, thiofluorene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole,benzimidazole, naphthimidazole, phenimidazole, pyridimidazole, pyrazine-imidazole, quinoxaline-imidazole, oxazole, benzoxazole, naphthoxazole, anthracenazole, phenoxazole, isoxazole, 1,2-thiazole, 1,3-thiazole, benzothiazole, pyridazine, benzopyridazine, pyrimidine, benzopyrimidine, quinoxaline, pyrazine, phenazine, 1,5-naphthyridine, carbazole, benzocholine, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole. 1,2,4,5-tetrazine, 1,2,3,4-tetrazine, 1,2,3,5-tetrazine, purine, pteridine, indolizine and benzothiadiazole. For the purposes of the present disclosure, aromatic and heteroaromatic ring systems are particularly considered to be, in addition to the above-mentioned aryl and heteroaryl groups, biphenylene, terphenylene, fluorene, spirofluorene, dihydrophenanthrene, tetrahydropyrene, cis-indenofluorene, or trans-indenofluorene.

In some embodiments, the CCM as described herein, wherein Ar¹ to Ar⁵ may be the same or different, at each occurrence, are independently selected from the group consisting of aromatic/ heteroaromatic groups with 5 to 20; preferably 5 to 18, more preferably 5 to 15 ring atoms; and most preferably 5 to 10 ring atoms; they may be unsubstituted or further substituted by one or two R¹ groups. Preferred aromatic/ heteraromatic groups include benzene, naphthalene, anthracene, phenanthrene, pyridine, pyrene, and thiophene.

For the purposes of the present disclosure, in some embodiments, each of Ar¹ to Ar⁵ is phenyl in the structural units of formulas (1)-(1e) or (2)-(2e).

In some embodiments, the CCM comprises a structural unit of formula (1a) or (2a):

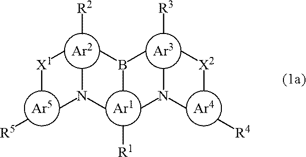

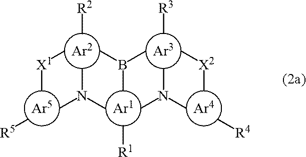

wherein each of X¹ and X² is O or S, and particularly preferably is O.

In some embodiments, the CCM comprises a structural unit of formula (1d), (2d), (1e), or (2e):

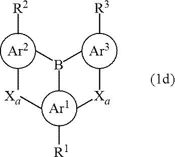

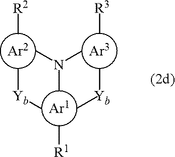

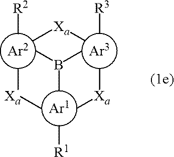

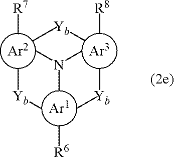

Preferably, each Y_{b} in the formulas (2d) and (2e) is independently C═O, O, P(═O)R⁹, S═O, or SO₂; and particularly preferably is C═O.

Preferably, each Xₐ in the formulas (1d) and (1e) is independently N(R⁹), C(R⁹R¹⁰), Si(R⁹R¹⁰), O, S.

In some embodiments, the structure of the CCM is shown below:

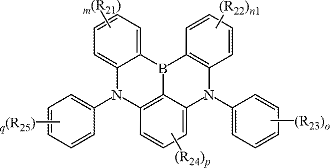

wherein R₂₁-R₂₅ are independently selected from the group consisting of H, D, a C₁-C₂₀ linear alkyl group, a C₁-C₂₀ linear alkoxy group, a C₁-C₂₀ linear thioalkoxy group, a C₃-C₂₀ branched/ cyclic alkyl group, a C₃-C₂₀ branched/ cyclic alkoxy group, a C₃-C₂₀ branched/ cyclic thioalkoxy group, a C₃-C₂₀ branched/ cyclic silyl group, a C₁-C₂₀ ketone group, a C₂-C₂₀ alkoxycarbonyl group, a C₇-C₂₀ aryloxycarbonyl group, a cyano group (—CN), a carbamoyl group (—C(═O)NH₂), a haloformyl group (—C(═O)—X where X represents a halogen atom), a formyl group (—C(═O)—H), an isocyano group, an isocyanate group, a thiocyanate/-isothiocyanate group, a hydroxyl group, a nitro group, a CF₃ group, Cl, Br, F, a substituted/-unsubstituted aromatic/ heteroaromatic group containing 5 to 40 ring atoms, an aryloxy/-heteroaryloxy group containing 5 to 40 ring atoms, and any combination thereof, wherein one or more of the substituent groups can form a monocyclic or polycyclic aliphatic or aromatic ring system with each other and/ or with the ring bonded to the groups; m, nl are integers from 0 to 4; o, q are integers from 0 to 5; p is an integer from 0 to 3.

In some embodiments, the color conversion material of the light emitting device as described herein is preferably selected from, but not limited to the following structural formulas:

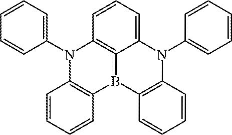

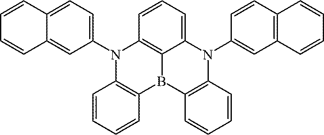

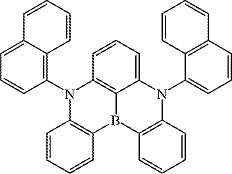

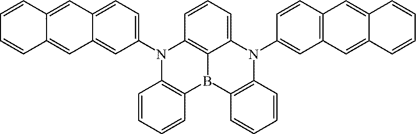

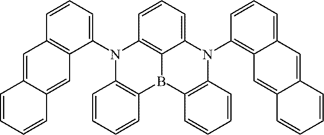

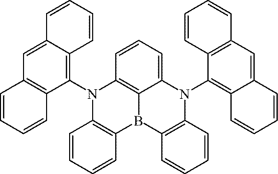

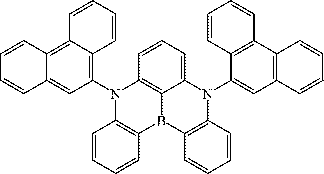

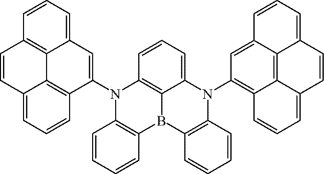

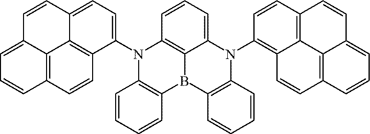

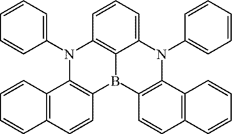

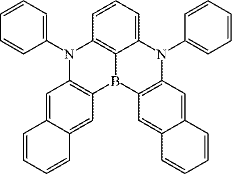

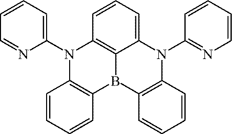

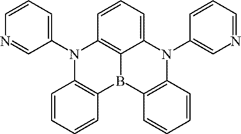

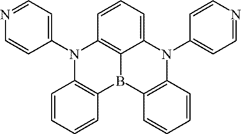

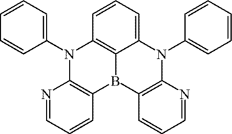

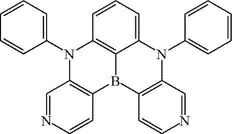

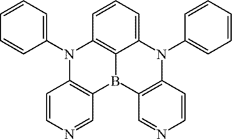

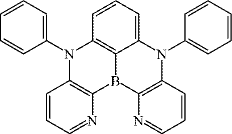

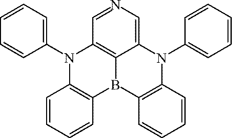

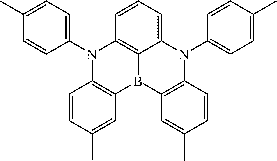

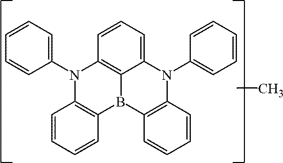

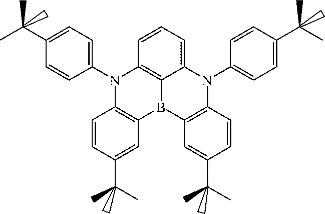

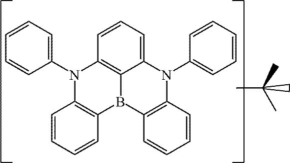

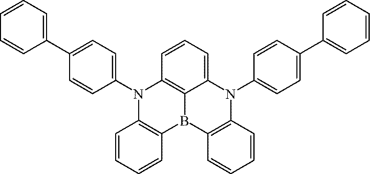

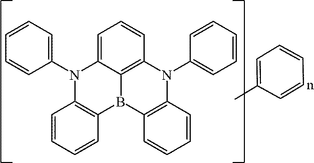

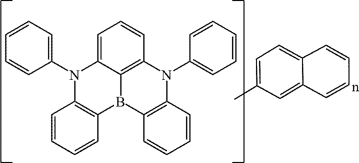

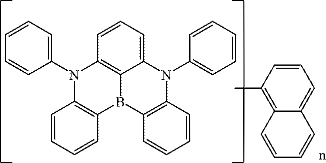

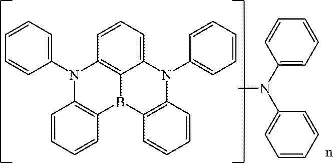

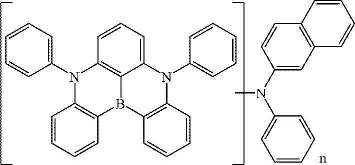

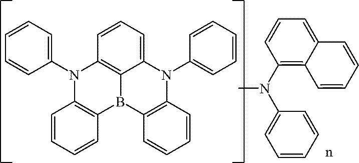

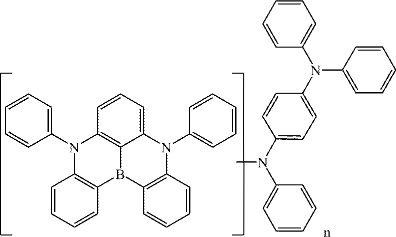

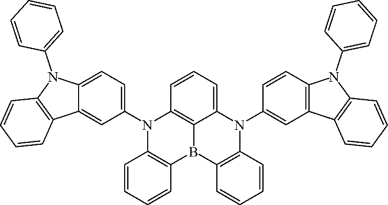

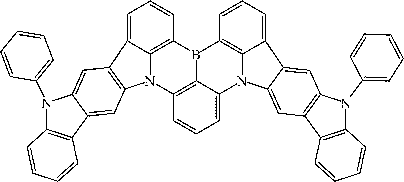

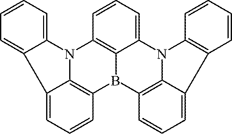

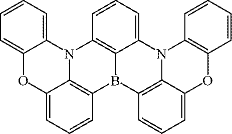

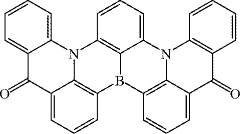

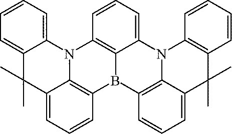

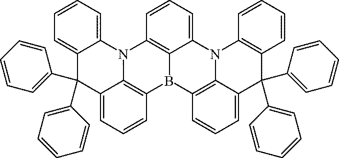

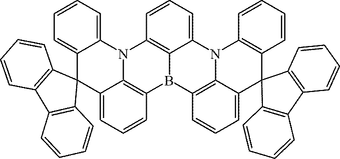

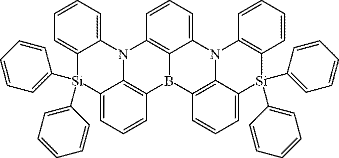

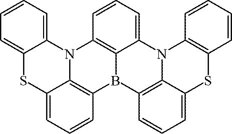

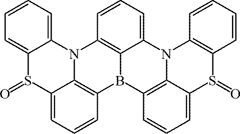

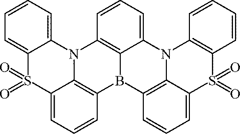

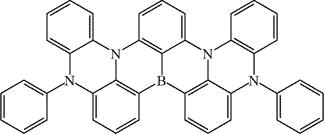

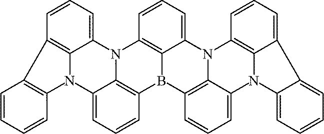

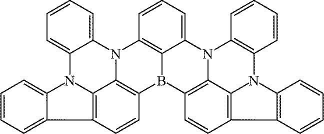

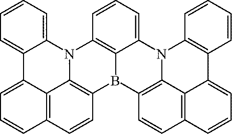

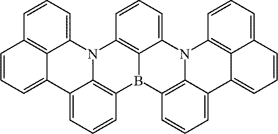

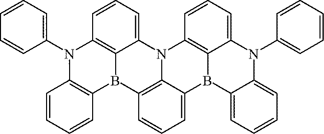

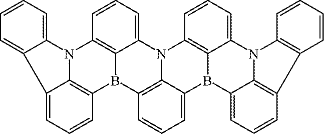

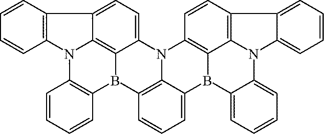

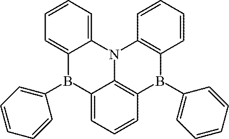

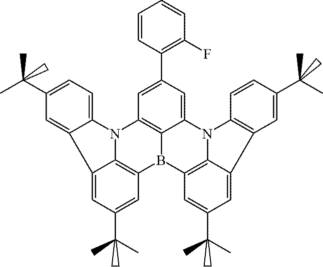

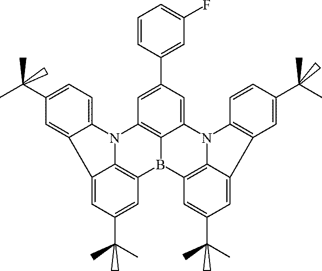

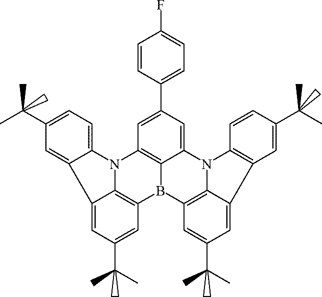

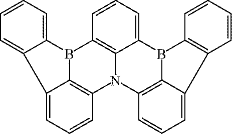

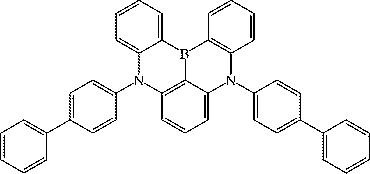

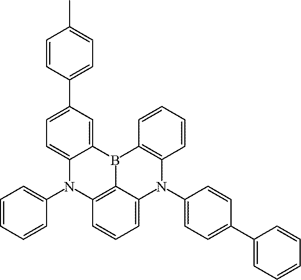

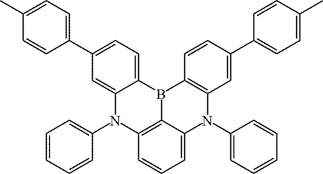

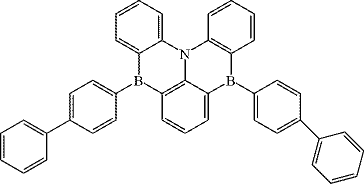

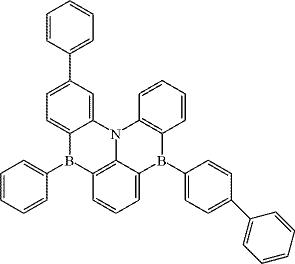

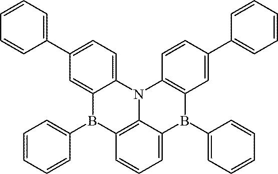

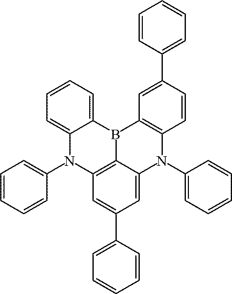

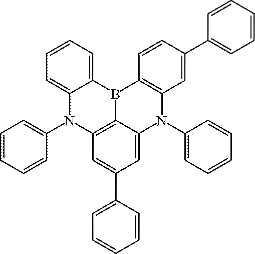

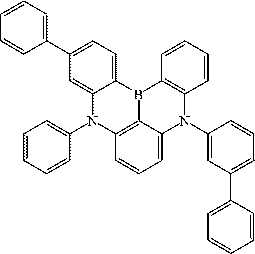

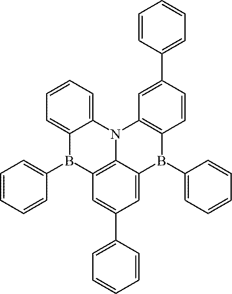

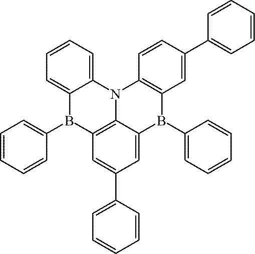

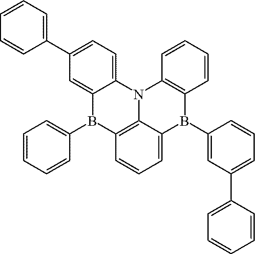

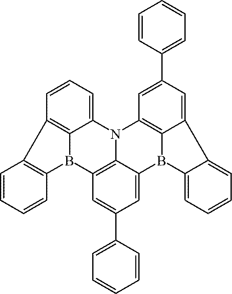

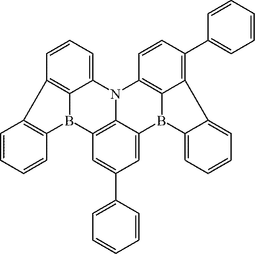

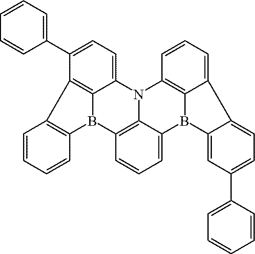

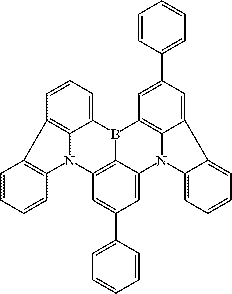

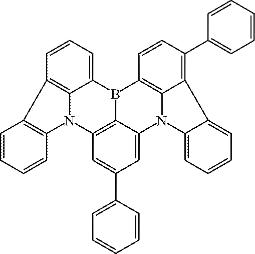

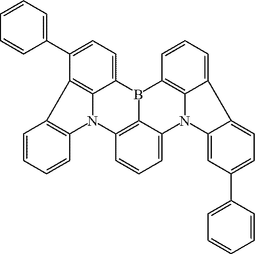

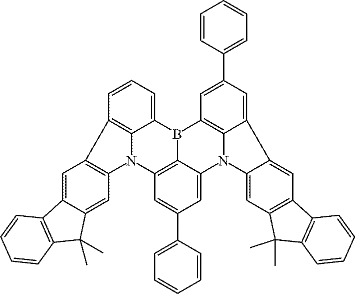

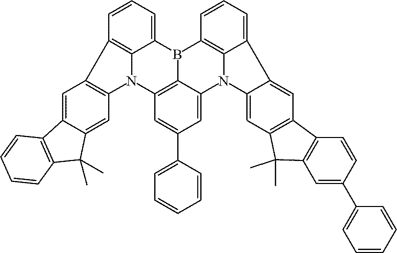

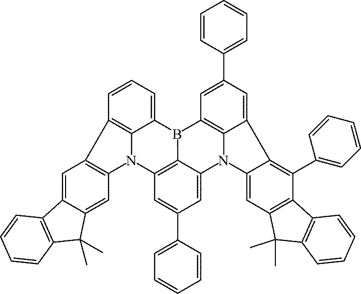

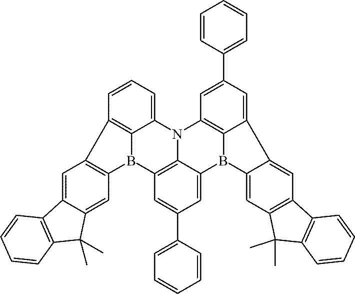

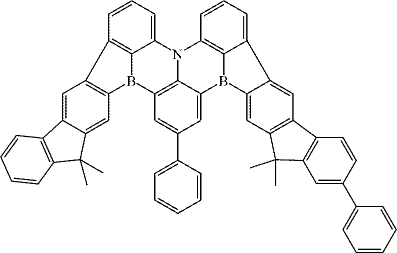

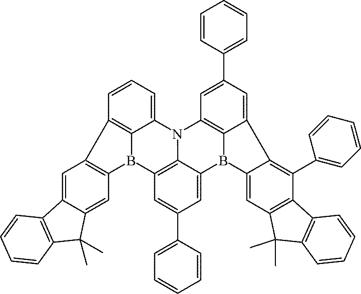

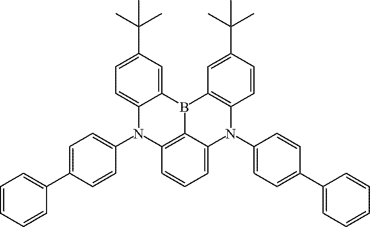

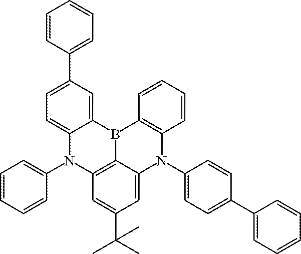

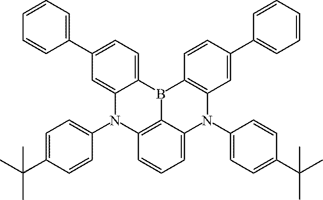

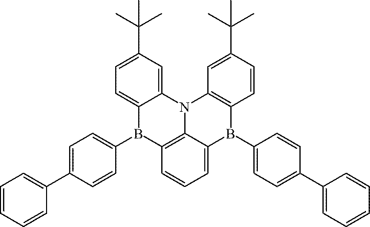

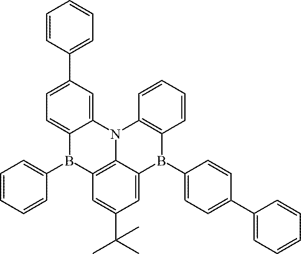

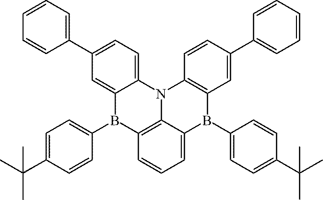

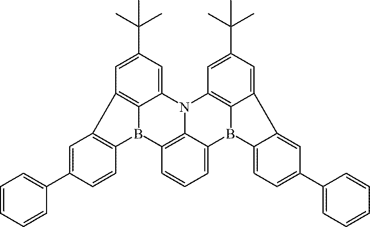

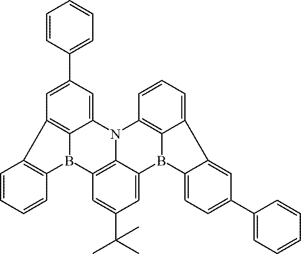

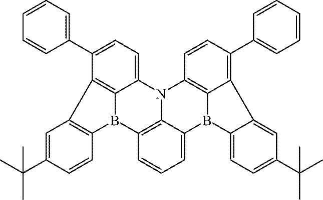

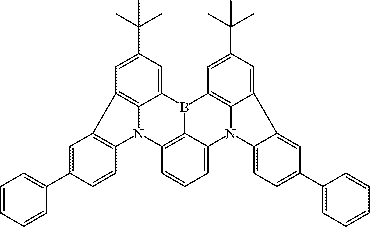

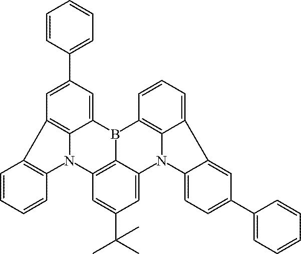

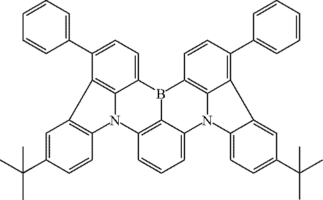

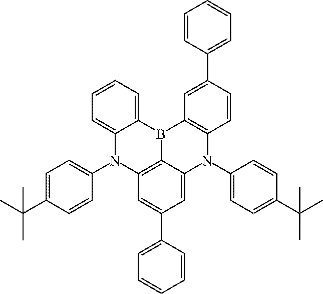

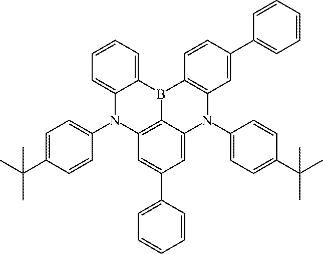

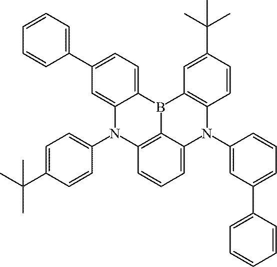

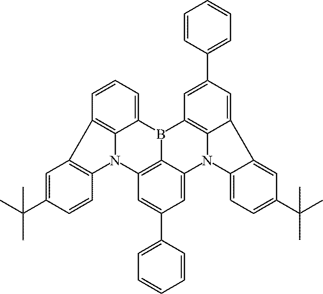

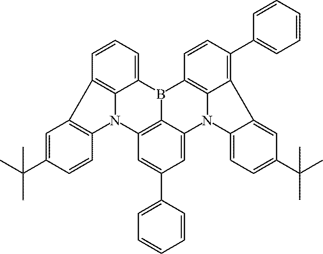

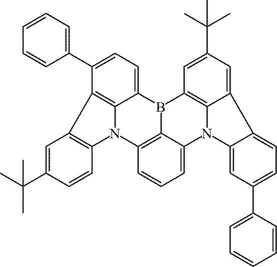

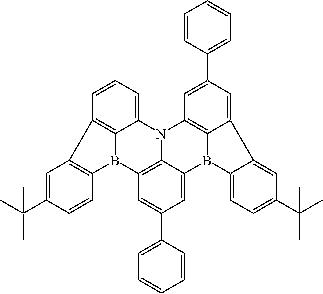

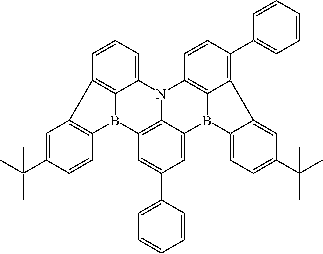

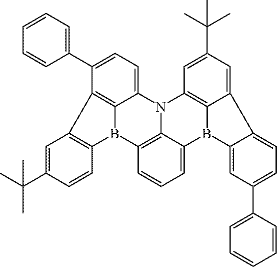

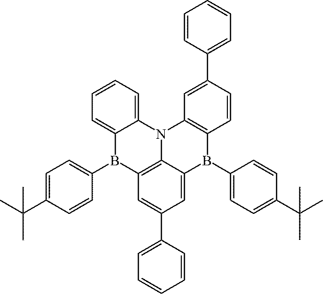

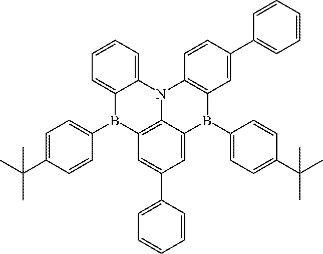

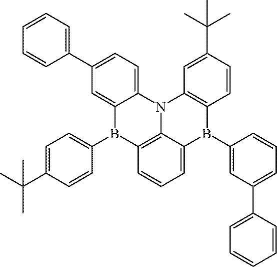

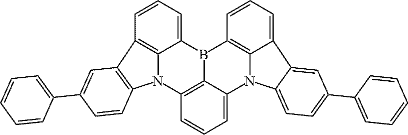

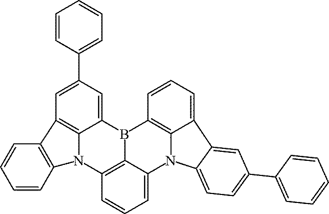

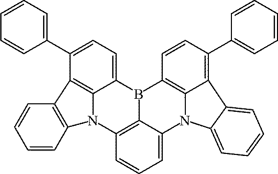

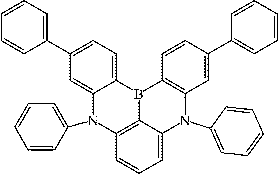

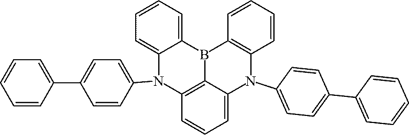

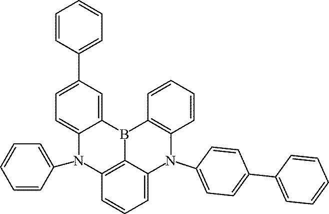

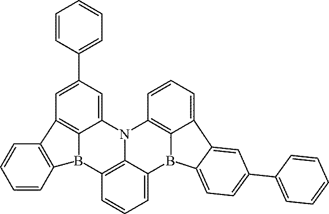

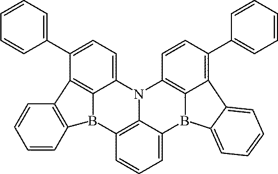

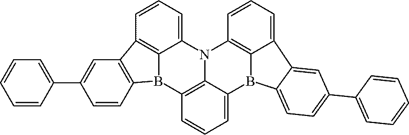

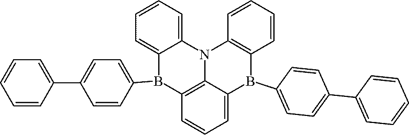

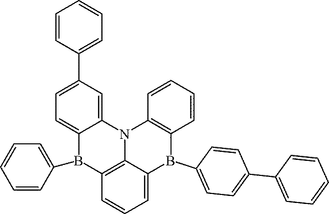

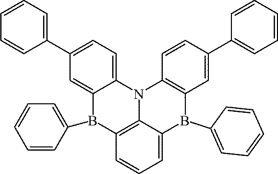

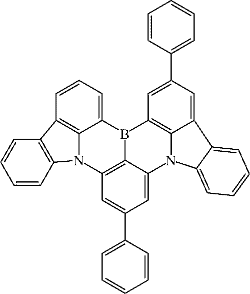

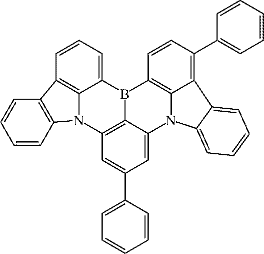

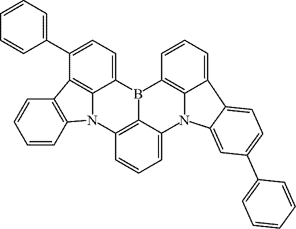

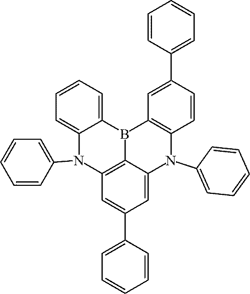

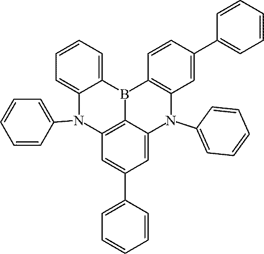

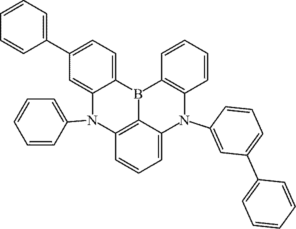

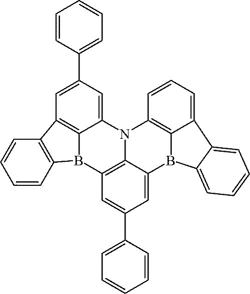

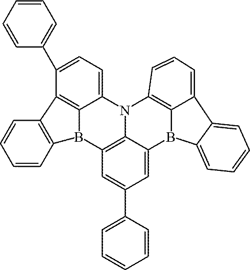

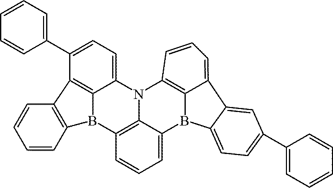

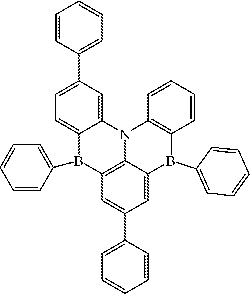

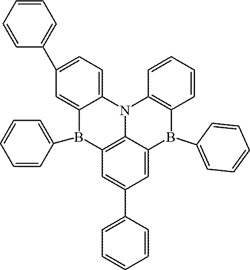

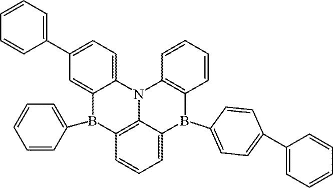

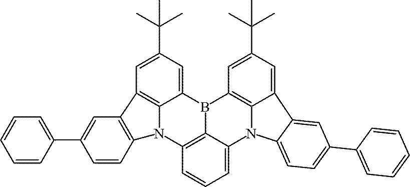

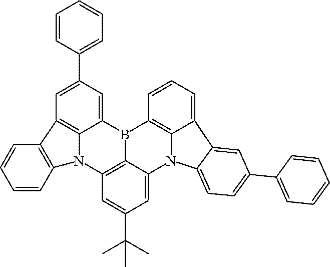

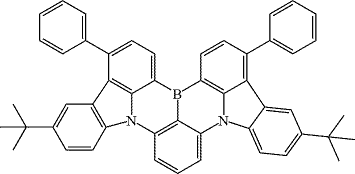

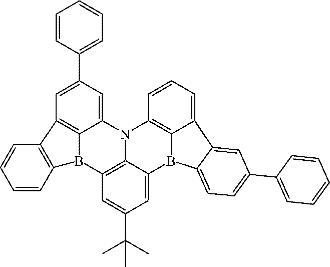

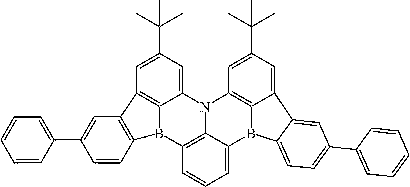

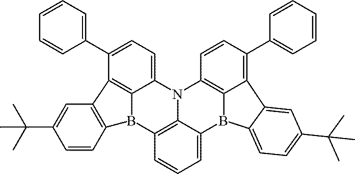

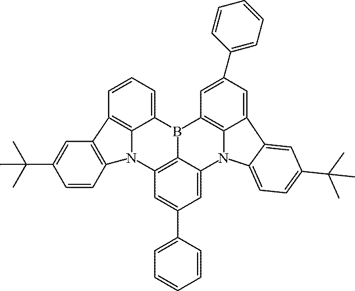

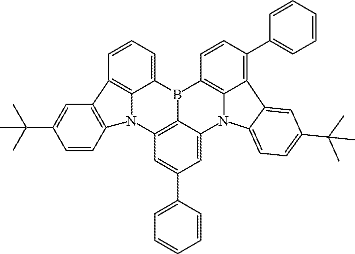

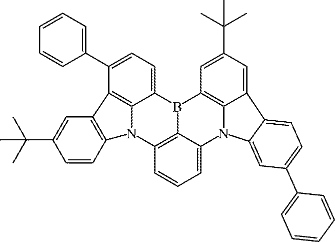

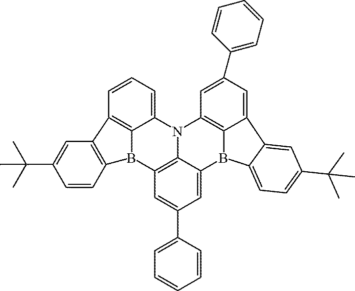

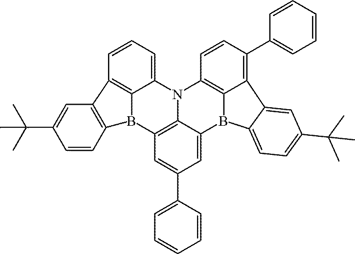

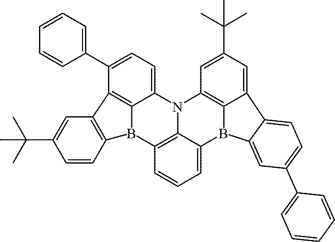

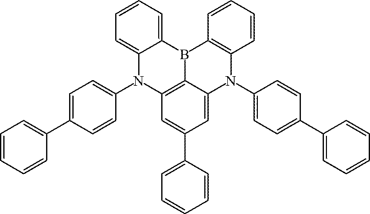

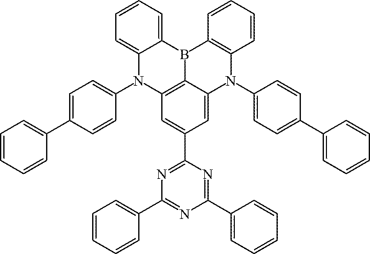

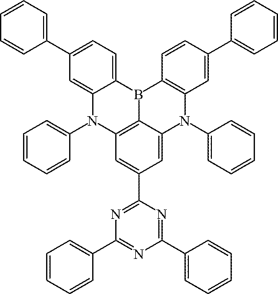

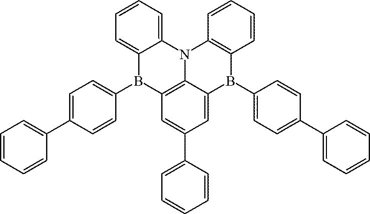

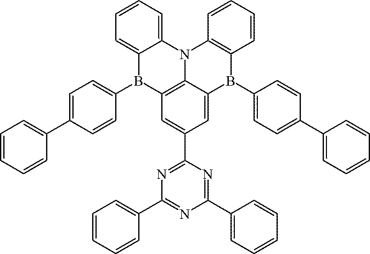

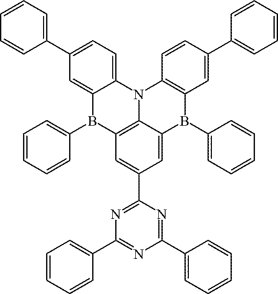

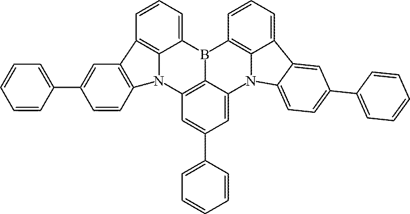

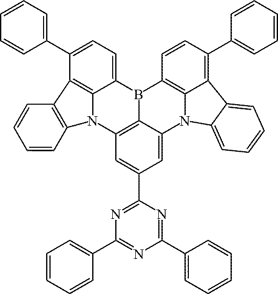

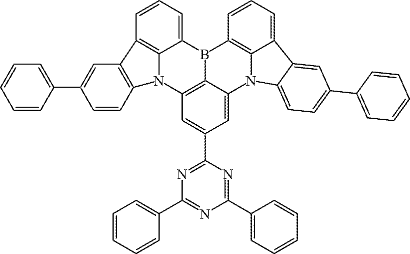

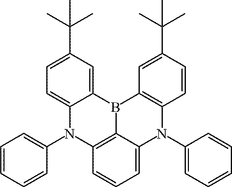

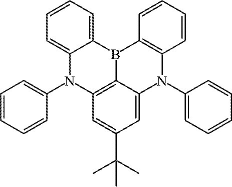

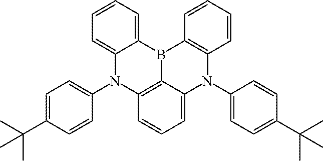

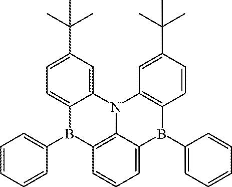

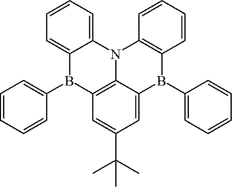

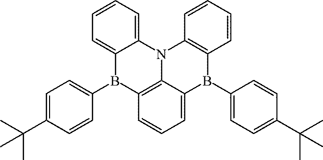

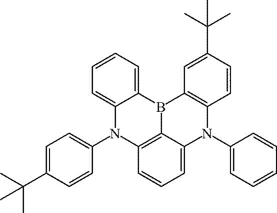

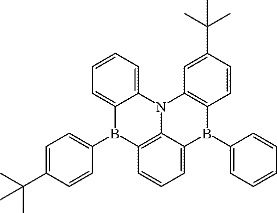

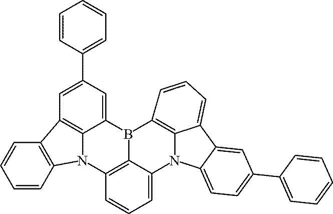

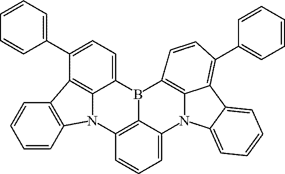

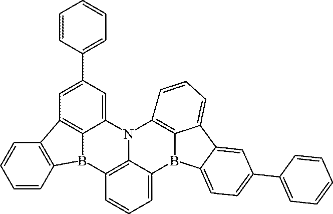

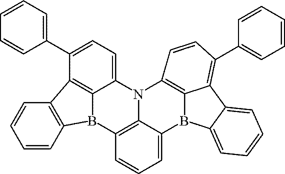

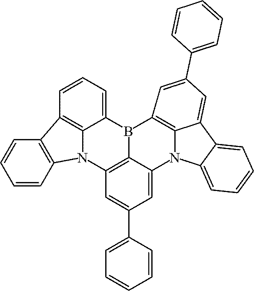

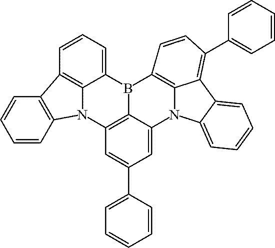

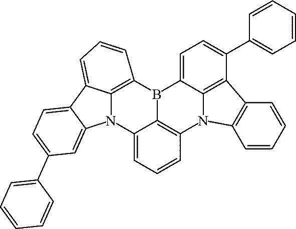

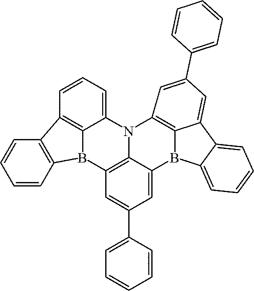

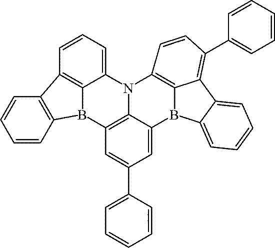

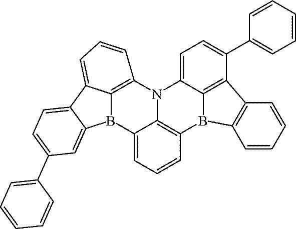

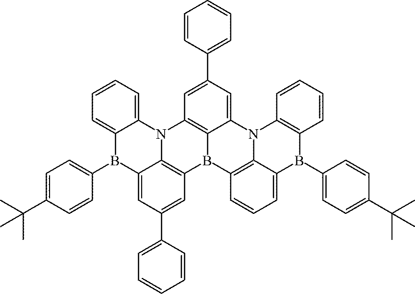

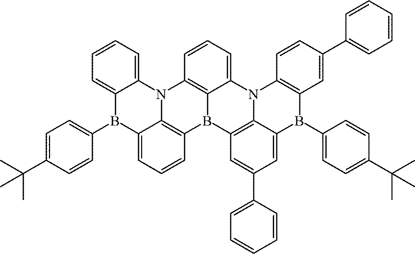

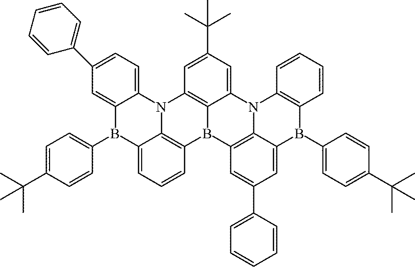

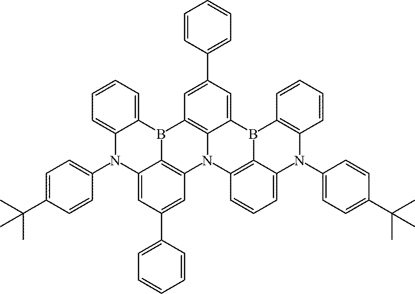

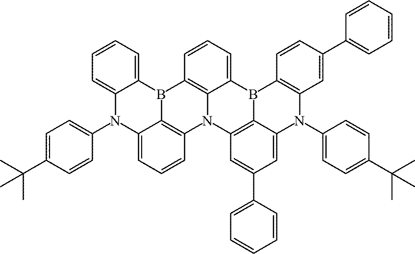

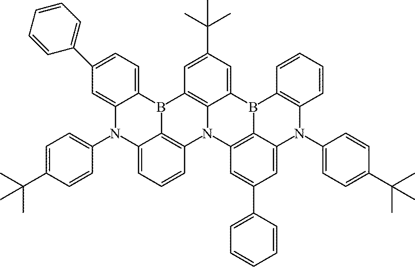

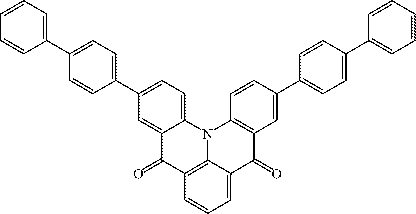

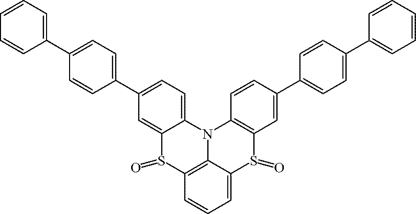

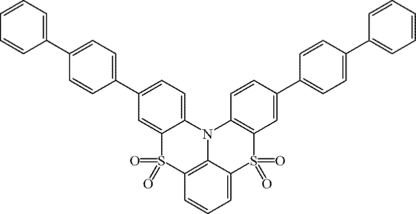

Wherein each n is an integer greater than 0.

In some embodiments, the electroluminescent unit of the light emitting device as described herein is selected from: an OLED (organic light emitting diode), a TFT-LCD (thin-film transistor liquid crystal display), a LED (light emitting diode), a QLED (quantum dot light emitting device), an OLEC (organic light emitting electrochemical cell), an OLET (organic light emitting transistor), a PeLED (perovskite light emitting device), a micro-LED (micro-light emitting diode), or other light emitting devices.

In some embodiments, the electroluminescent unit of the light emitting device as described herein is an OLED.

In some embodiments, the electroluminescent unit of the light emitting device as described herein is a LED.

In some embodiments, the color conversion layer of the light emitting device as described herein can absorb the light of the wavelength I and emit the light of wavelength II.

In some embodiments, in the light emitting device as described herein, the emission spectrum of the electroluminescent unit and the light absorption spectrum of the CCM at least partially overlap.

In some embodiments, in the light emitting device as described herein, the emission spectrum of the electroluminescent unit emits UV or blue light.

In some embodiments, the color conversion layer of the light emitting device as described herein emits the light of wavelength II, the FWHM of its spectrum is less than 40 nm, preferably less than 35 nm, more preferably less than 33 nm, and most preferably less than 30 nm.

In some embodiments, the color conversion layer of the light emitting device as described herein can be either an uniform thin layer or a patterned thin layer with a thickness of 20 nm to 20 µm, preferably less than 15 µm, more preferably less than 12 µm, even more preferably less than 10 µm, particularly preferably less than 8 µm, further preferably less than 6 µm, and most preferably less than 4 µm.

In some embodiments, the color conversion layer of the light emitting device as described herein can be prepared by vapor deposition, ink-jet printing, screen printing, gravure printing, post-coating photolithography, or other methods.

Taking vapor deposition as an example, where the color conversion material is placed into a heating crucible of the vacuum thermal evaporator, and heated under a vacuum of 1E-7Pa to vaporize. The vapor of the color conversion material then deposites onto the substrate to form a color conversion film. The deposition thickness can be controlled by tuning the evaporation rate and time, and specific patterns could be formed by using a mask.

In some embodiments, the color conversion layer (CCL) as described herein do not comprise any polymers or resins. Preferably, the color conversion layer is processed by the vapor deposition method as described above.

The color conversion layer can also be processed by inkjet printing, transfer printing, photolithography, or the like. In those cases, the color conversion materials as described herein should be dissolved in an organic solvent alone or together with other materials to form inks.

In another aspect, the present disclosure also provides a formulation or a printing ink. The formulation comprises at least one of the color conversion materials as described herein, and at least one organic solvent. The at least one organic solvent is selected from aromatic, heteroaromatic, esters, aromatic ketones, aromatic ethers, aliphatic ketones, aliphatic ethers, alicyclic, olefins, boronic esters, phosphoric esters, or mixtures of two or more of them.

In some embodiments, in the formulation as described herein, the at least one organic solvent are selected from aromatic or heteroaromatic-based solvents.

Examples of aromatic or heteroaromatic-based solvents suitable for the present disclosure include, but not limited to: p-diisopropylbenzene, amylbenzene, tetralin, cyclohexylbenzene, chloronaphtalene, 1,4-dimethylnaphthalene, 3-isopropylbenzene, p-methylisopropylbenzene, dipentylbenzene, tripentylbenzene, pentyltoluene, o-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, dihexylbenzene, dibutylbenzene, p-diiisopropylbenzene, cyclohexylbenzene, benzylbutylbenzene, dimethylnaphthalene, 3-isopropylbiphenyl, p-methylisopropylbenzene, 1-methylnaphthalene, 1,2,4-trichlorobenzene,4,4-difluorobenzenemethane, 1,2-dimethoxy-4-(1-propenyl) benzene, diphenylmethane, 2-phenylpyridine, 3 -phenylpyridine, N-methyldiphenylamine, 4-isopropylbipheny, 1,1,1 -bis(3,4-dimethylphenyl) ethane, 2-isopropylnaphthalene, quinoline, isoquinoline, methyl 2-furanecarboxylate, ethyl 2- furanicarboxylate, and the like.

Examples of aromatic ketone-based solvents suitable for the present disclosure include, but not limited to: 1-tetrahydronaphthalone, 2-tetrahydronaphthalone, 2-(phenylepoxy)tetrahydronaphthalone, 6-(methoxy)tetrahydronaphthalone, acetophenone, phenylacetone, benzophenone, and derivatives thereof such as 4-methyl acetophenone, 3-methyl acetophenone, 2-methyl acetophenone, 4-methyl propanone, 3-methyl propanone, 2-methyl propanone, and the like.

Examples of aromatic ether-based solvents suitable for the present disclosure include, but not limited to: 3-phenoxytoluene, butoxybenzene, p-anisaldehyde dimethyl acetal, tetrahydro-2-phenoxy-2H-pyran, 1,2-dimethoxy-4-(1-propenyl)benzene, 1,4-benzodioxane, 1,3-dipropylbenzene, 2,5-dimethoxytoluene, 4-ethylphenyl ether, 1,3-dipropoxybenzene, 1,2,4-trimethoxybenzene, 4-(1-propenyl)-1,2-dimethoxybenzene, 1,3-dimethoxybenzene, glycidyl phenyl ether, dibenzyl ether, 4-tert-butyl anisole, trans-anethole, 1,2-dimethoxybenzene, 1-methoxynaphthalene, diphenyl ether, 2-phenoxymethyl ether, 2-phenoxytetrahydrofuran, ethyl-2-naphthyl ether.

In some embodiments, in the formulation as described herein, the at least one organic solvent can be selected from aliphatic ketones, such as, 2-nonanone, 3-nonanone, 5-nonanone, 2-decanone, 2,5-hexanedione, 2,6,8-trimethyl-4-nonanone, fenchone, phoron, isophorone, din-amyl ketone, and the like; and the at least one organic solvent as described herein can be selected from aliphatic,ether, such as, dipentyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether, and the like.

In some embodiments, in the formulation as described herein, the at least one organic solvent can be selected from: ester-based solvents including alkyl octanoate, alkyl sebacate, alkyl stearate, alkyl benzoate, alkyl phenylacetate, alkyl cinnamate, alkyl oxalate, alkyl maleate, alkyl lactone, alkyl oleate, and the like. Particular preferred as octyl octanoate, diethyl sebacate, diallyl phthalate, or isononyl isononanoate.

The solvent can be used alone or as mixtures of two or more organic solvents.

In some embodiments, the formulation as described herein can further comprise another organic solvent. Examples of another organic solvent include, but not limited to: methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1,4 dioxane, acetone, methyl ethyl ketone, 1,2 dichloroethane, 3-phenoxytoluene, 1,1,1-trichloroethane, 1,1,2,2-tetrachloroethane, ethyl acetate, butyl acetate, dimethylformamide, dimethylacetamide, dimethylsulfoxide, tetrahydronaphthalene, decalin, indene, and/ or mixtures thereof.

In some embodiments, particularly suitable solvents for the present disclosure are solvents with Hansen solubility parameters in the following ranges:
δd (dispersion force) is in the range of 17.0 to 23.2 MPa^{½}, especially in the range of 18.5 to 21.0 MPa^{½};
δp (polarity force) is in the range of 0.2 to 12.5 MPa^{½}, especially in the range of 2.0 to 6.0 MPa^{½};
δh (hydrogen bonding force) is in the range of 0.9 to 14.2 MPa^{½}, especially in the range of 2.0 to 6.0 MPa^{½}.

In the formulation as described herein, the boiling points of the organic solvent should be taken into consideration for the selection. In the present disclosure, the boiling points of the organic solvent ≥150° C.; preferably ≥180° C.; more preferably ≥200° C.; further more preferably ≥250° C.; and most preferably ≥275° C. or ≥300° C. The boiling points in these ranges are beneficial in terms of preventing nozzle clogging of the inkjet printhead. The organic solvent can be evaporated to form a functional material film.

In some embodiments, the formulation as described herein is a solution.

In some embodiments, the formulation as described herein is a dispersion.

In yet another aspect, the present disclosure further provides the use of the formulation as coatings or printing inks in the preparation of organic electronic devices, particularly preferably by printing or coating processing methods.

Suitable printing or coating techniques include, but not limited to, ink-jet printing, nozzle printing, typographic printing, screen printing, dip coating, spin coating, blade coating, roller printing, torsional roll printing, planographic printing, flexographic printing, rotary printing, spray coating, brush coating, pad printing, slit type extrusion coating, and so on. Preferred techniques are gravure printing, nozzle printing and ink-jet printing. The solution or dispersion may additionally comprise one or more components, such as surfactants, lubricants,wetting agents, dispersing agents, hydrophobic agents, binders, etc, which are used to adjust the viscosity and film forming properties, or to improve adhesion, etc. For more information about printing technologys and their requirements for solutions, such as solvent, concentration, and viscosity, and the like, please refer to “Handbook of Print Media: Technologies and Production Methods”, edited by Helmut Kipphan, ISBN 3-540-67326-1.

The preparation methods as described herein, wherein the formed functional layer has a thickness of 5 nm to 1000 nm.

The color conversion material described herein appears in the ink with a concentration (by mass) of no less than 0.1 wt%. The color conversion efficiency of the color conversion layer can be improved by adjusting the concentration of the color conversion material in the ink and the thickness of the color conversion layer. In general, the higher the concentration of the color conversion material or the thickness of the layer, the higher the color conversion efficiency of the color conversion layer would be.

The formulation as described herein further comprises a polymer additive, which may be selected from, but not limited to the following materials: polyethylene, polypropylene, polystyrene, polycarbonate, polyacrylate, polyvinylpyrrolidone, polyvinyl alcohol, polyvinyl acetate, polyethylene glycol, polysiloxane, polyacrylonitrile, polyvinyl chloride, polyvinylidene chloride, polyethylene terephthalate, polybutylene terephthalate, polyvinyl butyrate, polyamide, polyoxymethylene, polyimide, polyether-ether-ketone, polysulfone, polyarylether, polyaramide, cellulose, modified cellulose, acetate, nitrocellulose, or the mixtures thereof.

Salts are difficult to be purified, and contains impurities, which may often influence/affect the opto-elecrtonic performance of the device. In some embodiments, for the purposes of the present disclosure, the color conversion layer (CCL) does not comprise any salts, and the color conversion layer preferably does not comprise any organic acid salts formed by organic acids and metals. In terms of cost, the present disclosure preferably excludes organic acid salts with transition metals or lanthanide elements.

In some embodiments, the electroluminescent unit of the light emitting device is a LED.

In some embodiments, the electroluminescent unit of the light emitting devices is an OLED comprising a substrate, an anode, at least one light emitting layer, and a cathode.

The substrate should be opaque or transparent. A transparent substrate could be used to produce a transparent light emitting device (for example: Bulovic et al., Nature 1996, 380, p29, and Gu et al., Appl. Phys. Lett. 1996, 68, p2606). Substrates may be either rigid or elastic. Preferably, the substrates should have a smooth surface. A substrate free of surface defects is particularly desirable. In some embodiments, the substrates are flexible and can be selected from a polymer film or plastic with a glass transition temperature Tg over 150° C., preferably over 200° C., more preferably over 250° C., and most preferably over 300° C. Examples of the suitable flexible substrates include poly (ethylene terephthalate) (PET) and polyethylene glycol (2,6 - naphthalene) (PEN).

The choice of anodes may include a conductive metal, a metal oxide, or a conductive polymer. The anode should be able to easily inject holes into a hole-injection layer (HIL) or a hole-transport layer (HTL), or a light emitting layer. In some embodiments, the absolute value of the difference between the work function of the anode and the highest occupied molecular orbital (HOMO) energy level of the emitter of the emitting layer, or the HOMO energy level/valence band energy level of the p-type semiconductor material for the hole injection layer (HIL)/ hole transport layer (HTL)/ electron blocking layer (EBL) is less than 0.5 eV, preferably less than 0.3 eV, more preferably less than 0.2 eV. Examples of anode materials may include, but not limited to: Al, Cu, Au, Ag, Mg, Fe, Co, Ni, Mn, Pd, Pt, ITO, aluminum doped zinc oxide (AZO), and the like. Other suitable anode materials are known and can be readily selected for use by one of ordinary skill in the art. The anode material can be deposited using any suitable technique, such as a suitable physical vapor deposition method, including RF magnetron sputtering, vacuum thermal evaporation, e-beam, etc. In some embodiments, the anode is patterned. Patterned conductive ITO substrates are commercially available and can be used to produce the devices as described herein.

The choice of cathode may include a conductive metal or a metal oxide. The cathode should be able to easily inject electrons into the EIL, the ETL, or the directly into the emitting layer. In some embodiments, the absolute value of the difference between the work function of the cathode and the LUMO energy level of the emitter of the emitting layer, or the lowest unoccupied molecular rrbital (LUMO) energy level/ conduction band energy level of the n-type semiconductor material for electron injection layer (EIL)/ electron transport layer (ETL)/ hole blocking layer (HBL) is less than 0.5 eV, preferably less than 0.3 eV, most preferably less than 0.2 eV. In principle, all materials that may be used as cathodes for OLEDs are possible to apply as cathode materials for the present disclosure. Examples of cathode materials include, but not limited to: Al, Au, Ag, Ca, Ba, Mg, LiF/ Al, MgAg alloys, BaF₂/ Al, Cu, Fe, Co, Ni, Mn, Pd, Pt, ITO, and the like. The cathode material can be deposited using any suitable technique, such as the suitable physical vapor deposition method, including RF magnetron sputtering, vacuum thermal evaporation, e-beam, and the like.

The OLED device may also comprise other functional layers, such as a hole injection layer (HIL), a hole transport layer (HTL), an electron blocking layer (EBL), an electron injection layer (EIL), an electron transport layer (ETL), or a hole blocking layer (HBL). Materials suitable for use in these functional layers are described in details above and in WO2010135519A1, US20090134784A1, and WO201110277A1, the contents of the these three documents are hereby incorporated herein for reference .

The light emitting device as described herein, wherein the emitting wavelength of the light emitting device is between 300 nm and 1000 nm, preferably between 350 nm and 900 nm, more preferably between 400 nm and 800 nm.

In yet another aspect, the present disclosure further provides the application of the light emitting device as described herein in various electronic devices, including but not limited to, display device, lighting device, light source, sensor, and the like.

In yet another aspect, the present disclosure further provides a display device, comprising a number of sub-pixels, at least one of the sub-pixel comprising a light emitting device as described herein.

Preferably, either the red sub-pixel or the green sub-pixel of the display device comprises a light emitting device as described herein.

In some embodiments, the display device is a multi-color display device, and the display device with narrow-FWHM comprising at least two types of the emitting devices selected from the red, the green and the blue light emitting devices as pixels, different pixels are arranged alternatinvely into array to form a display panel.

The present disclosure will be described below in conjunction with the preferred embodiments, but the present disclosure is not limited to the following embodiments. It should be understood that the scope of the present disclosure is covered by the scope of the claims of the present disclosure, and those skilled in the art should understand that certain changes may be made to the embodiments of the present disclosure.

### SPECIFIC EMBODIMENT

### Example 1: Red Narrow-FWHM Light Emitting Device1

The red color conversion layer 1 comprises the molecule of the following structure:

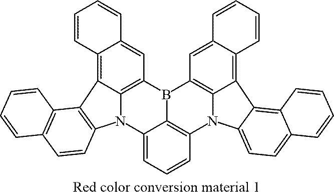

Molecules of the above structure were placed into the heated crucible of the vacuum thermal evaporation device, and the molecules were evaporated and deposited onto the glass side of the green OLED device at a vacuum degree of 1E-7Pa, so that the red color conversion layer with a thickness of 100 nm was formed. [image]
The present embodiment further provides a structure of the green OLED light emitting device, wherein the anode electrode is an ITO layer;
The hole injection layer was a layer of HATCN (Dipyrazino[2,3-f:2′,3′-h]quinoxaline-2,3,6,7,10,11-hexacarbonitrile);
The hole transport layer was a layer of NPB (N, N′-bis(1-naphthalenyl)-N, N′-bisphenyl-(1,1′-biphenyl)-4,4′-diamine) layer;
The light emitting layer was a doped layer of Ir(ppy)₃ (tris(2-phenylpyridinato-C2,N)iridium(III)) with CBP (4,4′-Bis(9-carbazolyl)-1,1′-biphenyl).

The electron transport layer was a layer of TPBI (1,3,5 - tris (1 - phenyl-1 H-benzimidazol-2 - yl) benzene) .

### Example 2: Green Color Converter 1

The color conversion layer of the green sub-pixel contains the molecule of the following structure:

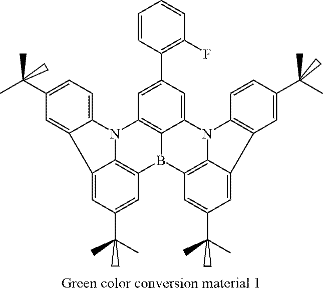

Molecules of the above structure were dissolved in methyl acrylate at 2%wt, a thin film with a thickness of 10 µm was formed on the surface of the blue GaN LED substrate by coating. After being irradiated with 365 nm ultraviolet light for 5 minutes, the methyl acrylate was polymerized to form the solid thin film, i. e. the color conversion layer. The color conversion layer can absorb blue light from GaN LEDs with a peak between 400-465 nm and emit green light between 490-530 nm with a color coordinate of (0.16, 0.60).

In order to achieve multi-color display by using the color converters to simultaneously realize multi-color emission, the present disclosure also provides multiple additional display technology solutions.

The first display technical scheme is shown in the following figure:

| | | | |
|---|---|---|---|
| GaN LED Edge-lit | Polarizer | | |
| | Blue Color Filter | Green Color Filter | Red Coloer Filter |

Polarizer
LCD Module
Polarizer
Red, Green and Blue Color Conversion Layer
Light Guide Plate

A red, green and blue three-color color conversion layer was added on the top of a light guide plate of a liquid crystal display, and the color conversion layer comprises the following three molecules:

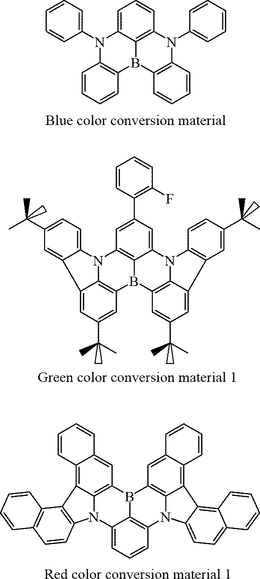

A preparation method of the color conversion layer is described as follows:

The above blue color conversion material, green color conversion material 1 and red color conversion material 1 were dissolved in a mixture solvent of tetrahydronaphthalene: toluene = 3:2 in the ratio of 5 mg/ml, 3 mg/ml and 2 mg/ml respectively. At the same time, 15 mg/ml of the polystyrene, 5 mg/ml of silicon dioxide nanospheres with a diameter of 3-5 µm were added to the solution. Through slit coating, a thin film with a thickness of about 100 um was formed on the surface of the electroluminescent device or a thin film as a color conversion layer for red, green and blue colors.

### Example 3: Further Color Converters

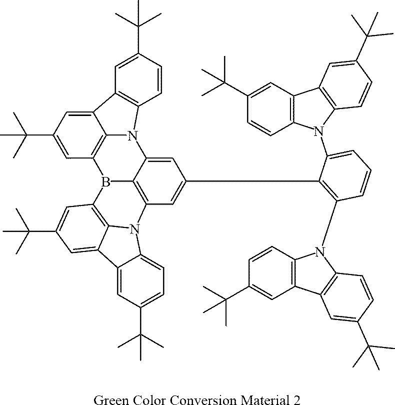

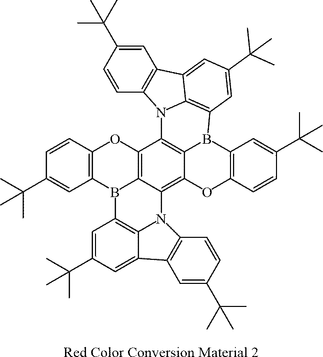

The synthesis of the green color conversion material 2 can be referred to (DOI: 10.1002/anie.202113206); the synthesis of the red color conversion material 2 can be referred to (DOI: 10.1002/adma.202201442).

The green color conversion material 2 and red color conversion material 2 were dissolved in a mixture solvent of tetrahydronaphthalene: toluene = 3:2 in the ratio of 5 mg/ml, and 1.5 mg/ml respectively. At the same time, 15 mg/ml of the polystyrene, 5 mg/ml of silicon dioxide nanospheres of 3-5 µm diameter were added to the solution to form the ink. Through slit coating using the ink, a thin film with a thickness of about 100 µm was formed on the surface of the electroluminescent device or a thin film as a color conversion layer for green and red.

The second display technology scheme is shown in the following figure:

[image]

A red, green and blue three-color display device, comprising the following components:
The green color converter, the red color converter and the transparent film layer are arranged alternately into an array to form three types of pixels;
A blue self-emitting device was disposed below the above three film layers, the blue self-emitting device emits blue light with an emission peak between 400 nm and 490 nm, with the blue light emits toward the green color converter and the red color converter according to example 3 and the transparent film layer, respectively; through the green color converter, a green emission with the emission peak between 490 nm and 550 nm is generated; through the red color converter, a red emission with the emission peak between 550 nm and 700 nm is generated; through the transparent film layer, the blue light with the emission peak between 400 nm and 490 nm remains;
The blue self-emitting device being used in the present embodiment is a organic electroluminescent device, with the structure of: Ag(16 nm)/ Yb(1 nm)/ TPBi(30 nm)/ 26 DCzPPY: 10 wt% FirPic(30 nm)/ NPB(180 nm)/ HATCN(10 nm)/ ITO(10 nm)/Ag(100 nm).

wherein the anode electrode is an ITO layer;
The hole injection layer is a HATCN (Dipyrazino[2,3-f:2′,3′-h]quinoxaline-2,3,6,7,10,11-hexacarbonitrile) layer;
The hole transport layer is the a NPB (N, N′-bis(1-naphthalenyl)-N, N′-bisphenyl-(1,1′-biphenyl)-4,4′-diamine) layer; the light emitting layer is a layer of FirPic (Bis[2-(4,6-difluorophenyl)pyridinato-C2,N](picolinato)iridium(III)) and 26DCzPPY (2,6-bis(3-(9H-carbazol-9-yl)phenyl)pyridine).The electron transport layer is a layer of TPBi (1,3,5-tris(1-phenyl-1H-benzimidazol-2-yl)benzene).

For the purposes of the present disclosure, the structure of the display devices are not limited thereto, and as long as the display technical solution of the present disclosure is applied, the purposes of the present disclosure can be achieved, and the convertible embodiments fall within the scope of protection of the present disclosure.

It should be noted that the above two techniques only describe the structure of the narrow-FWHM light emitting devices in the display device of the present disclosure. In order to achieve the complete display effect, a display device should also include, and may not limited to, the following components:

1) The thin-film transistors set below the narrow-FWHM light emitting device and connected to the self-emitting part of the light emitting devices through a circuit, which serve to control the brightness.

2) The pixel circuits set below the thin-film transistor, which serve to control each pixel on the array, so as to display a pattern.

3) The substrate set below in the pixel circuit, which provides mechanical support for all the above-mentioned narrow-FWHM light emitting devices, the thin-film transistors and the pixel circuits.

For further description of using the color conversion layers to realize multicolor light display, please refer to the following technical materials: Chinese patents CN102067729B and CN106556949B.

What is claimed is:

1. A light emitting device, comprising an electroluminescent unit and a color conversion layer, wherein the color conversion layer comprises at least one color conversion material having a structural unit of formula (1) or (2): 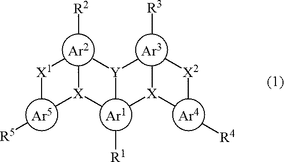 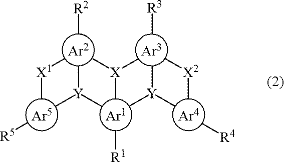
wherein:
each X independently represents N, C(R⁶), or Si(R⁶);
each Y independently represents B, P═O, C(R⁶), or Si(R⁶);
each of Ar¹, Ar², and Ar³ is independently an aromatic group containing 5 to 24 ring atoms, or a heteroaromatic group containing 5 to 24 ring atoms;
each of Ar⁴ and Ar⁵ is independently null, an aromatic group containing 5 to 24 ring atoms, or a heteroaromatic group containing 5 to 24 ring atoms;
when neither Ar⁴ nor Ar⁵ is null, each X is selected from the group consisting of N, C(R⁶) and Si(R⁶), each Y is selected from the group consisting of B, P═O, C(R⁶) and Si(R⁶) ;
when Ar⁴ and/ or Ar⁵ is null, the corresponding X and Y are each independently selected from the group consisting of N(R⁶), C(R⁶R⁷), Si(R⁶R⁷), C═O, O, C═N(R⁶), C═C(R⁶R⁷), P(R⁶), P(═O)R⁶, S, S═O and SO₂;
each of X¹, X² is independently null or a bridging group;
R¹ to R⁷ are independently selected from the group consisting of —H, -D, —F, —Cl, —Br, —I, —CN, —NO₂, —CF₃, B(OR₂)₂, Si(R₂)₃, a C₁-C₂₀ linear alkyl group, a C₁-C₂₀ linear haloalkyl group, a C₁-C₂₀ linear alkoxy group, a C₁-C₂₀ linear thioalkoxy group, a C₃-C₂₀ branched/ cyclic alkyl group, a C₃-C₂₀ branched/ cyclic haloalkyl group, a C₃-C₂₀ branched/ cyclic alkoxy group, a C₃-C₂₀ branched/ cyclic thioalkoxy group, a C₃-C₂₀ branched/ cyclic silyl group, a C₁-C₂₀ ketone group, a C₂-C₂₀ alkoxycarbonyl group, a C₇-C₂₀ aryloxycarbonyl group, a cyano group, a carbamoyl group, a haloformyl group, a formyl group, an isocyano group, an isocyanate group, a thiocyanate/ isothiocyanate group, a hydroxyl group, a nitro group, a CF₃ group, Cl, Br, F, a substituted/ unsubstituted aromatic/ heteroaromatic group containing 5 to 40 ring atoms, an aryloxy/ heteroaryloxy group containing 5 to 40 ring atoms, an arylamine/ heteroarylamine group containing 5 to 40 ring atoms, a disubstituted unit in any position of the above substituents and any combination thereof, wherein one or more of the substituent groups can form a monocyclic or polycyclic aliphatic or aromatic ring system with each other and/or with the ring bonded to the groups.

2. The light emitting device of claim 1, wherein the color conversion layer comprises at least one color conversion material having a structure unit of formula (1a) or (2a). 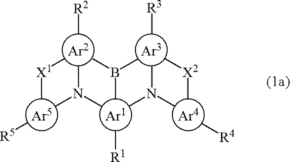 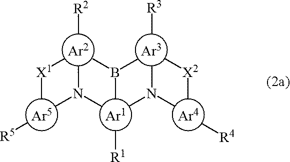
.

3. The light emitting device of claim 1, wherein each of Ar¹, Ar², Ar³, Ar⁴, and Ar⁵ in the formula (1) or (2) is independently selected from the group consisting of: 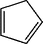 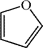 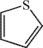 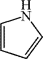 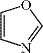 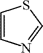 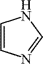 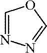 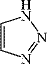 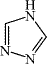 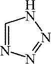 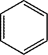 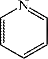 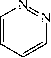 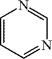 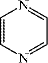 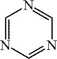 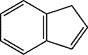 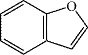 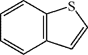 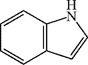 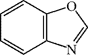 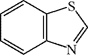 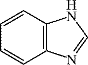 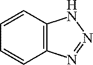 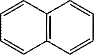 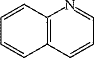 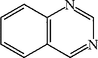 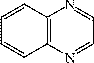 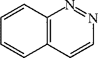 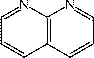 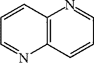 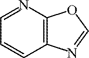 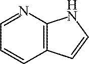 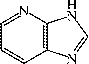 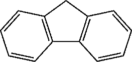 [SMILES: c1ccc2c(c1)Cc1ccccc1-2] 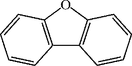 [SMILES: c1ccc2c(c1)oc1ccccc12] 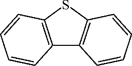 [SMILES: c1ccc2c(c1)sc1ccccc12] 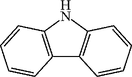 [SMILES: c1ccc2c(c1)[nH]c1ccccc12] 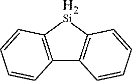 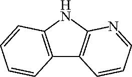 [SMILES: c1ccc2c(c1)[nH]c1ncccc12] 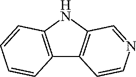 [SMILES: c1ccc2c(c1)[nH]c1cnccc12] 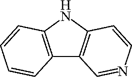 [SMILES: c1ccc2c(c1)[nH]c1ccncc12] 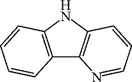 [SMILES: c1ccc2c(c1)[nH]c1cccnc12] 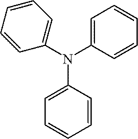 [SMILES: c1ccc(N(c2ccccc2)c2ccccc2)cc1] 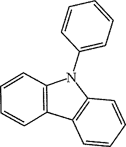 [SMILES: c1ccc(-n2c3ccccc3c3ccccc32)cc1] 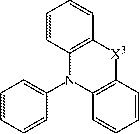 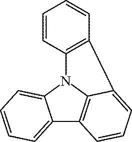 [SMILES: c1ccc2c(c1)c1cccc3c4ccccc4n2c13] 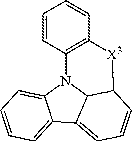 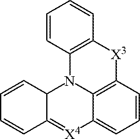 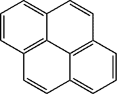 [SMILES: c1cc2ccc3cccc4ccc(c1)c2c34] 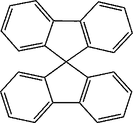 [SMILES: c1ccc2c(c1)-c1ccccc1C21c2ccccc2-c2ccccc21] 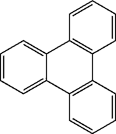 [SMILES: c1ccc2c(c1)c1ccccc1c1ccccc21]
wherein each of X³ and X⁴ is independently null or a bridging group.

4. The light emitting device of claim 1, wherein the color conversion material is selected from the group consisting of: 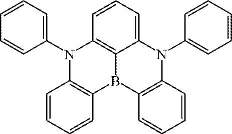 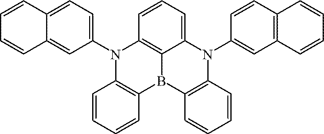 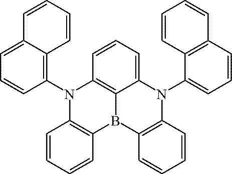 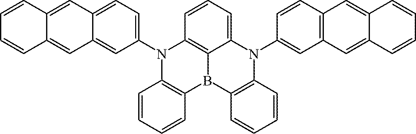 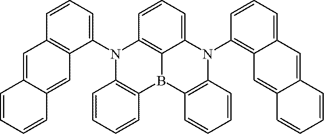 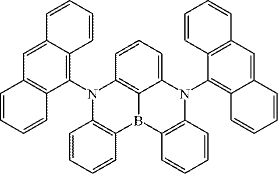 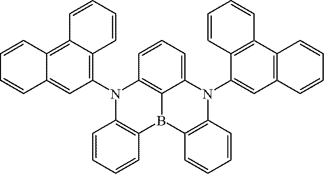 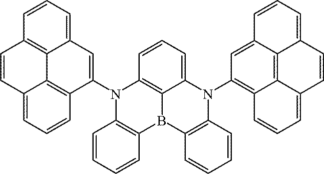 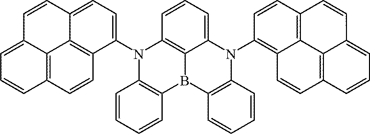 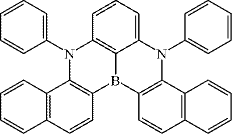 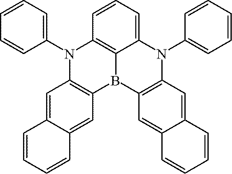 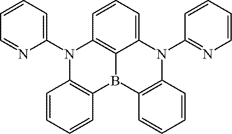 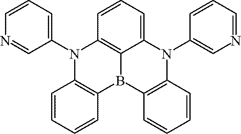 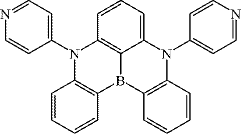 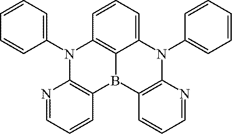 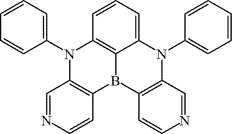 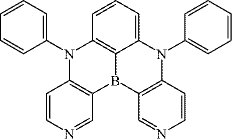 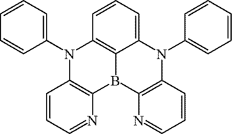 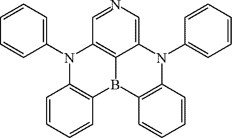 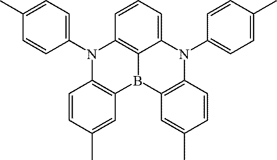 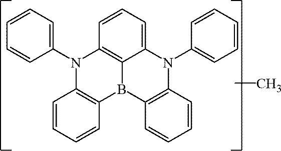 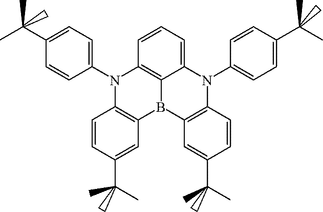 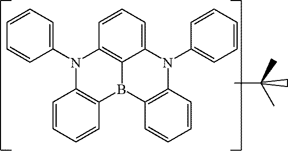 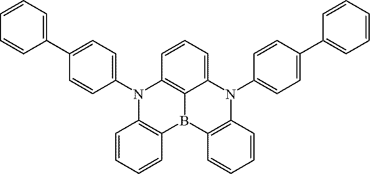 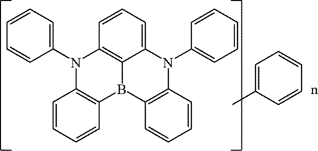 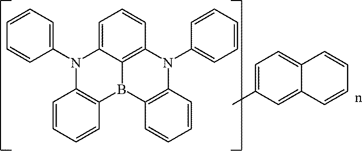 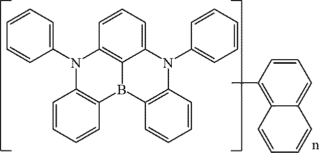 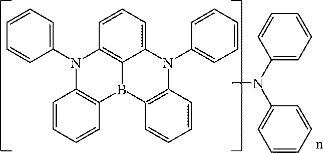 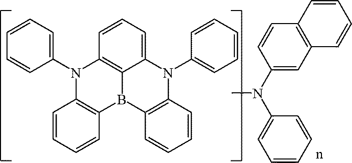 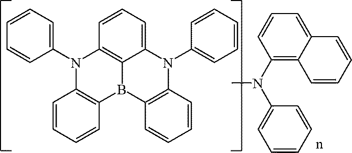 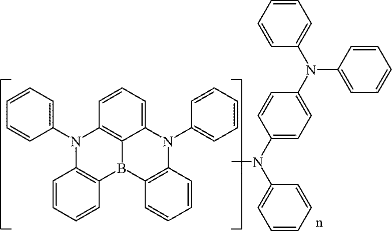 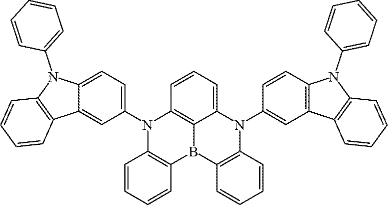 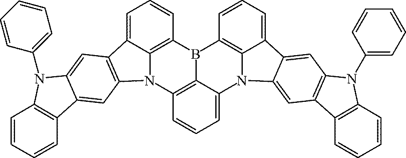 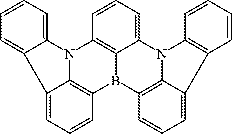 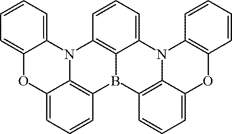 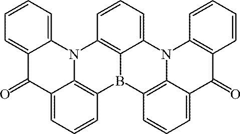 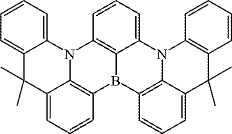 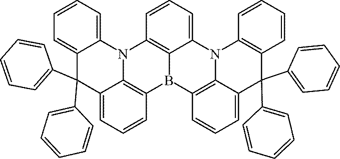 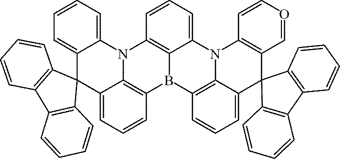 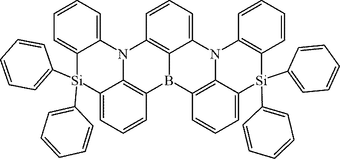 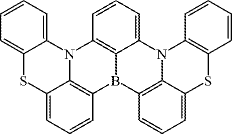 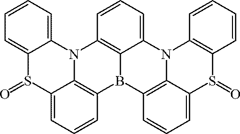 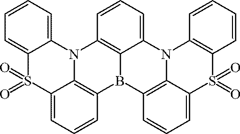 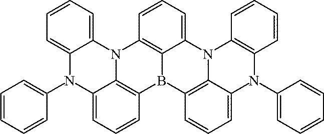 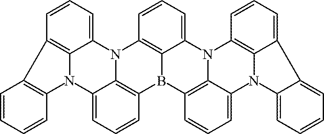 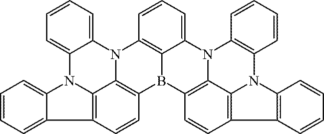 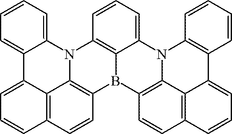 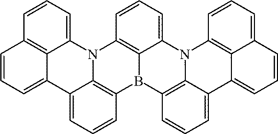 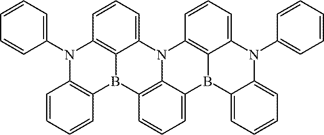 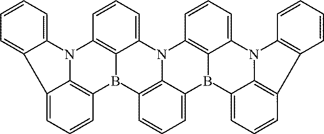 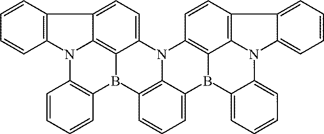 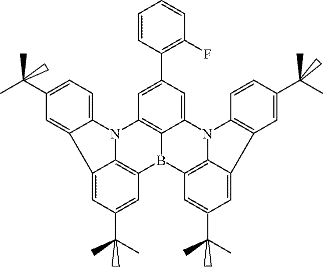 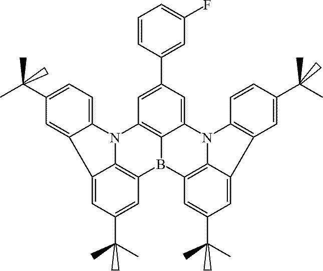 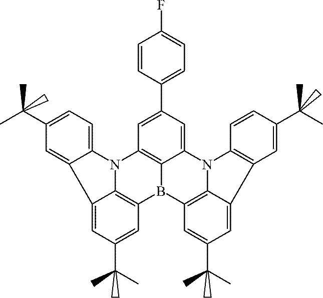
Wherein each n is an integer greater than 0.

5. The light emitting device of claim 1, wherein the electroluminescent unit is selected from an OLED, a TFT-LCD, a LED, a QLED, an OLEC, an OLET, a PeLED, or a micro-LED.

6. The light emitting device of claim 1, wherein the color conversion layer can absorb the light of wavelength I and emit the light of wavelength II.

7. The light emitting device of claim 1, wherein the emission spectrum of the electroluminescent unit at least partially overlaps with the absorption spectrum of the color conversion material.

8. The light emitting device of claim 1, wherein the electroluminescent unit emits UV or blue light.

9. The light emitting device of claim 6, wherein the FWHM of the spectrum of wavelength II emitted by the color conversion layer is less than 40 nm.

10. The light emitting device of claim 1, wherein the color conversion layer can be either an uniform thin layer or a patterned thin layer with a thickness of 20 nm to 20 µm.

11. The light emitting device of claim 1, wherein the color conversion layer can be prepared by vapor deposition, ink-jet printing, screen printing, gravure printing, or post-coating photolithography.

12. A display device, comprising a number of sub-pixels, at least one of the sub-pixels comprising a light emitting device according to claim 1.

13. The display device of claim 12, wherein either the red sub-pixel or the green sub-pixels comprises a light emitting device according to claim 1.

14. The display device of claim 12, comprising at least two types of the light emitting devices selected from the red, the green and the blue light emitting devices according to claim 1 as pixels, different pixels are arranged alternatively into array to form a display panel.
